(19) United States
(12) Patent Application Publication
(10) Pub. No.: US 2020/0077478 A1
(43) Pub. Date: Mar. 5, 2020

(54) LIGHT-EMITTING APPARATUS, OPTICAL MEASURING INSTRUMENT, IMAGE FORMING APPARATUS, AND LIGHT-EMITTING DEVICE

(71) Applicant: FUJI XEROX CO., LTD., Tokyo (JP)

(72) Inventor: Takashi KONDO, Kanagawa (JP)

(73) Assignee: FUJI XEROX CO., LTD., TOKYO (JP)

(21) Appl. No.: 16/535,087

(22) Filed: Aug. 8, 2019

(30) Foreign Application Priority Data
Aug. 29, 2018 (JP) 2018-160812

(51) Int. Cl. H05B 33/08; G09G 3/3266; H01L 29/74; H01L 33/08; H01L 27/32

(52) U.S. Cl. CPC H05B 33/0815; G09G 3/3266; H01L 27/32; H01L 33/08; H01L 29/74

(57) ABSTRACT

A light-emitting apparatus includes plural first transfer elements, plural second transfer elements, plural first driving elements, plural setting elements, plural second driving elements, and plural light-emitting elements. The plural first transfer elements enter an ON state in order. The plural second transfer elements enter the ON state in order. The plural first driving elements are connected to the plural first transfer elements and are shifted to a state in which the plural first driving elements are able to be shifted to the ON state when the first transfer elements enter the ON state. The plural setting elements are connected to the plural second transfer elements and are shifted to a state in which the plural setting elements are able to be shifted to the ON state when the second transfer elements enter the ON state. The plural second driving elements are connected to the plural setting elements and are shifted to a state in which the plural second driving elements are able to be shifted to the ON state when the setting elements enter the ON state. The plural light-emitting elements are connected to the plural first driving elements and the plural second driving elements and emit light or increase light emission intensity when the first driving elements and the second driving elements enter the ON state. Plural sets each including one of the first driving elements, one of the second driving elements, and one of the light-emitting elements are connected to at least one of the plural setting elements. The plural light-emitting elements are arranged two-dimensionally.

### CROSS-REFERENCE TO RELATED APPLICATIONS

This application is based on and claims priority under 35 USC 119 from Japanese Patent Application No. 2018-160812 filed Aug. 29, 2018.

### BACKGROUND

### (i) Technical Field

The present disclosure relates to a light-emitting apparatus, an optical measuring instrument, an image forming apparatus, and a light-emitting device.

### (ii) Related Art

In Japanese Unexamined Patent Application Publication No. 1-238962, a light-emitting element array is described which is configured such that a large number of light-emitting elements whose threshold voltage or threshold current is able to be controlled by light from the outside are arranged one-dimensionally, two-dimensionally, or three-dimensionally and at least part of light generated from each of the light-emitting elements is incident to another light-emitting element in the vicinity of the light-emitting element, a clock line for externally applying voltage or current being connected to each of the light-emitting elements.

In Japanese Unexamined Patent Application Publication No. 2017-174906, a light-emitting chip C is described which includes a plurality of transfer thyristors T that enter an ON state in order, a plurality of setting thyristors S that are connected to the corresponding plurality of transfer thyristors T and are shifted to a state in which the plurality of setting thyristors S are able to be shifted to the ON state when the transfer thyristors T enter the ON state, and a plurality of light-emitting diodes LED that are laminated at the plurality of setting thyristors S by tunnel junction and emit light or increase the amount of light emission when the setting thyristors S enter the ON state.

In Japanese Unexamined Patent Application Publication No. 2001-353902, a self-scanning two-dimensional light-emitting array is described in which two light emission signal lines φIj and φI(j+1) of a light-emitting part are connected on a light emission start point side into one line φIj·(j+1), light-emitting elements are arranged two-dimensionally in n rows by l columns (l is an integer of 1 or more), the anode electrode of a light-emitting element L(j,k) is connected to a light emission signal line φIj in the nth row, the gate electrode of a light-emitting element (j,2k−1) in an odd-number row is connected to a gate signal G2i−1 line in the (2i−1)th column, and the gate electrode of a light-emitting element (j,2k) in an even-number row is connected to a gate signal G2i line in the 2ith column.

### SUMMARY

In a light-emitting apparatus in which by transferring the ON state of a plurality of transfer elements in order, light-emitting elements connected to the transfer elements are set to an ON state or an OFF state and caused to emit light, the light-emitting elements may be required to be turned ON two-dimensionally in a parallel manner.

Aspects of non-limiting embodiments of the present disclosure relate to a light-emitting apparatus in which light-emitting elements are turned ON two-dimensionally in a parallel manner.

Aspects of certain non-limiting embodiments of the present disclosure address the above advantages and/or other advantages not described above. However, aspects of the non-limiting embodiments are not required to address the advantages described above, and aspects of the non-limiting embodiments of the present disclosure may not address advantages described above.

According to an aspect of the present disclosure, there is provided a light-emitting apparatus including plural first transfer elements, plural second transfer elements, plural first driving elements, plural setting elements, plural second driving elements, and plural light-emitting elements. The plural first transfer elements enter an ON state in order. The plural second transfer elements enter the ON state in order. The plural first driving elements are connected to the plural first transfer elements and are shifted to a state in which the plural first driving elements are able to be shifted to the ON state when the first transfer elements enter the ON state. The plural setting elements are connected to the plural second transfer elements and are shifted to a state in which the plural setting elements are able to be shifted to the ON state when the second transfer elements enter the ON state. The plural second driving elements are connected to the plural setting elements and are shifted to a state in which the plural second driving elements are able to be shifted to the ON state when the setting elements enter the ON state. The plural light-emitting elements are connected to the plural first driving elements and the plural second driving elements and emit light or increase light emission intensity when the first driving elements and the second driving elements enter the ON state. Plural sets each including one of the first driving elements, one of the second driving elements, and one of the light-emitting elements are connected to at least one of the plural setting elements. The plural light-emitting elements are arranged two-dimensionally.

### BRIEF DESCRIPTION OF THE DRAWINGS

Exemplary embodiments of the present disclosure will be described in detail based on the following figures, wherein:

FIG. 1 is an equivalent circuit diagram of a light-emitting apparatus;

FIG. 2 is a diagram illustrating an example of a planar layout of a light-emitting part;

FIG. 3A is a cross-sectional view of upper driving thyristor/lower driving thyristor/laser diode taken along line IIIA-IIIA of FIG. 2;

FIG. 3B is a cross-sectional view of upper driving thyristor/lower driving thyristor/laser diode taken along line IIIB-IIIB of FIG. 2;

FIG. 4 is an enlarged plan view of an island including (upper) driving thyristor/(lower) driving thyristor/laser diode;

FIG. 5A is a cross-sectional view of an island including a transfer thyristor, a coupling diode, and a connection diode in an h-direction transfer part taken along line VA-VA of FIG. 2;

FIG. 5B is a cross-sectional view of an island including a transfer thyristor, a coupling diode, and a connection diode in a v-direction transfer part and an island including a setting thyristor and a connection resistor, taken along line VB-VB of FIG. 2;

FIG. 6A is a diagram for explaining an operation of a thyristor in a case where a voltage reduction layer is not provided;

FIG. 6B is a diagram for explaining an operation of a thyristor in a case where a voltage reduction layer is provided;

FIG. 6C illustrates thyristor characteristics;

FIG. 7 is a diagram for explaining band gap energy of materials forming a semiconductor layer multilayer body;

FIG. 8A is a schematic energy band diagram of a lamination structure of a laser diode and a lower driving thyristor;

FIG. 8B is an energy band diagram of a tunnel junction layer in a reverse-bias state;

FIG. 8C illustrates current-voltage characteristics of the tunnel junction layer;

FIG. 9 is a diagram illustrating an example of the light-emitting apparatus controlling ON/OFF of laser diodes;

FIG. 10 is a timing chart for driving the light-emitting apparatus;

FIG. 11A is a diagram for explaining an operation in a state immediately before time a1;

FIG. 11B is a diagram for explaining an operation in a state immediately after the time a1;

FIG. 12A is a diagram for explaining an operation in a state immediately after time a2;

FIG. 12B is a diagram for explaining an operation in a state immediately after time b;

FIG. 13A is a diagram for explaining an operation in a state immediately after time b1;

FIG. 13B is a diagram for explaining an operation in a state immediately after time b2;

FIG. 14 is a diagram for explaining an operation at time f1;

FIG. 15 is a diagram for explaining an operation at time i;

FIG. 16 is a diagram for explaining an optical measuring instrument including the light-emitting apparatus;

and

FIG. 17 is a diagram for explaining an image forming apparatus including the light-emitting apparatus.

### DETAILED DESCRIPTION

Hereinafter, exemplary embodiments of the present disclosure will be described in detail with reference to the attached drawings.

### [Light Emitting Apparatus]

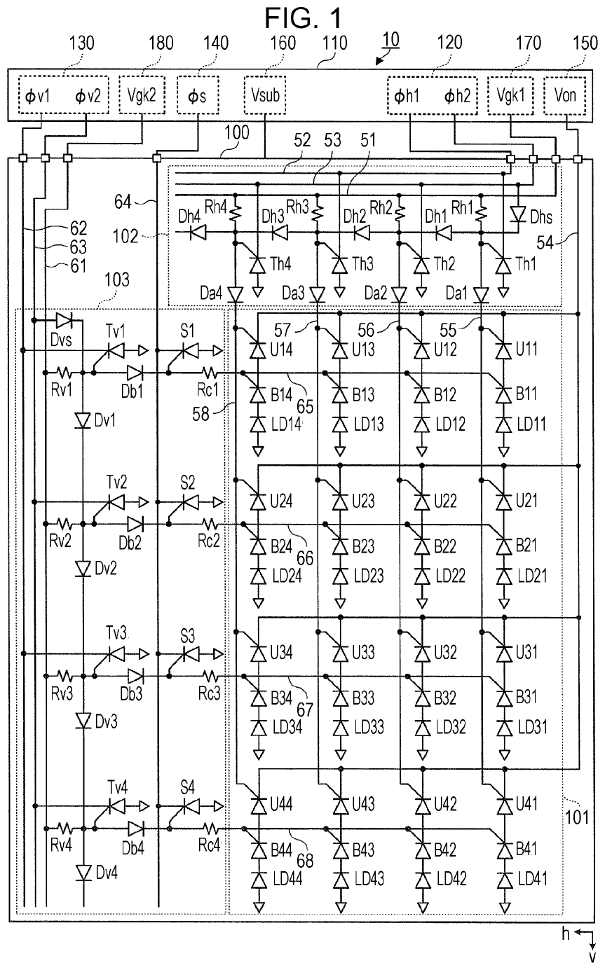

FIG. 1 is an equivalent circuit diagram of a light-emitting apparatus 10. In FIG. 1, diodes, thyristors, resistors, and the like explained below are represented by signs generally used. The same applies to other drawings. Furthermore, in FIG. 1, for example, a reference potential (hereinafter, denoted by a reference potential Vsub), which is a ground potential (GND), is represented by “∇”. Thyristors are elements each including an anode, a cathode, and at least one gate, entering an ON state when a voltage of a certain level or more is applied to the gate while voltage is being applied between the anode and the cathode or entering the ON state when voltage is applied between the anode and the cathode while a voltage of a certain level or more is being applied to the gate, and maintaining the ON state while a current of a holding current or more is flowing between the anode and the cathode.

The light-emitting apparatus 10 includes a light-emitting unit 100 and a controller 110.

The light-emitting unit 100 includes a light-emitting element part 101, a horizontal direction transfer part 102, and a vertical direction transfer part 103. The horizontal direction transfer part 102 will be denoted by an h-direction transfer part 102, and the vertical direction transfer part 103 will be denoted by a v-direction transfer part 103. The horizontal direction and the vertical direction will be described later.

The light-emitting element part 101 includes laser diodes LD that emit laser light as an example of light-emitting elements. The laser diodes LD are, for example, vertical cavity surface emitting lasers (VCSELs). As described later, the light-emitting unit 100 is configured as a self-scanning light emitting element array (self-scanning light emitting device (SLED)).

In FIG. 1, the light-emitting element part 101 includes sixteen laser diodes LD that are arranged in a 4 by 4 matrix (two-dimensionally). The term “two-dimensional” represents a state in which the number of dimensions is two, for example, spreading in the horizontal direction and the vertical direction as described below. In the drawing of FIG. 1, the direction going from the right to the left will be defined as the horizontal direction and will be represented by “h” or the “h direction”. The direction going from the top to the bottom will be defined as the vertical direction and will be represented by “v” or the “v direction”. Herein, the h direction and the v direction are orthogonal to each other. However, the h direction and the v direction are not necessarily orthogonal to each other.

The light-emitting element part 101 includes a row in which laser diodes LD11, LD12, LD13, and LD14 are arranged in the h direction, a row in which laser diodes LD21, LD22, LD23, and LD24 are arranged in the h direction, a row in which laser diodes LD31, LD32, LD33, and LD34 are arranged in the h direction, and a row in which laser diodes LD41, LD42, LD43, and LD44 are arranged in the h direction. These rows are arranged in the v direction in this order. That is, the light-emitting unit 100 includes a column in which the laser diodes LD11, LD21, LD31, and LD41 are arranged in the v direction, a column in which the laser diodes LD12, LD22, LD32, and LD42 are arranged in the v direction, a column in which the laser diodes LD13, LD23, LD33 and LD43 are arranged in the v direction, and a column in which the laser diodes LD14, LD24, LD34, and LD44 are arranged in the v direction.

As described above, in the case where the laser diodes LD are to be distinguished from one another, a two-digit number such as “LD11” is added to each laser diode LD. However, “i” and “j” may be assigned in place of numbers in the h direction and the v direction, respectively, and a laser diode LD may be denoted by “LDji”. The same applies to other cases. In the case where a number is to be assigned only in the h direction, “i” may be assigned in place of each number. In the case where a number is to be assigned only in the v direction, “j” may be assigned in place of each number. In this example, i and j are integers from 1 to 4.

The light-emitting element part 101 also includes sixteen driving thyristors B and sixteen driving thyristors U. Each of the driving thyristors B and U is connected to a corresponding one of the laser diodes LD. The laser diodes LD, the driving thyristors B, and the driving thyristors U are connected in series in the order of the laser diodes LD, the driving thyristors B, and the driving thyristors U. That is, a laser diode LD, a driving thyristor B, and a driving thyristor U form a set. Therefore, the same number as that assigned to a laser diode LD connected to driving thyristors B and U is assigned to the driving thyristors B and U, so that the driving thyristors B and U are distinguished from other driving thyristors B and U.

Herein, a plurality of components that are distinguished from one another by numbers assigned thereto represent components that are assigned numbers before and after “to” and numbers between the numbers before and after “to”. For example, the laser diodes LD 11 to 14 represent the laser diode LD11, the laser diode LD12, the laser diode LD13, and the laser diode LD14 in this order.

The h-direction transfer part 102 includes four transfer thyristors Th, four coupling diodes Dh, four connection diodes Da, and four resistors Rh. Furthermore, the h-direction transfer part 102 includes a start diode Dhs.

The transfer thyristors Th are arranged in the h direction in the order of the transfer thyristors Th1, Th2, Th3, and Th4. The coupling diodes Dh are arranged in the h direction in the order of the coupling diodes Dh1, Dh2, Dh3, and Dh4. The coupling diodes Dh1, Dh2, and Dh3 are provided between the transfer thyristors Th1 and Th2, between the transfer thyristors Th2 and Th3, and between the transfer thyristors Th3 and Th4, respectively. The coupling diode Dh4 is provided on a side of the transfer thyristor Th4 that is opposite the side on which the coupling diode Dh3 is provided. The connection diodes Da and the resistors Rh are arranged in the h direction in a similar manner.

The transfer thyristors Th, the coupling diodes Dh, the connection diodes Da, and the resistors Rh are arranged in the h direction, and therefore, single-digit numbers are assigned to the transfer thyristors Th, the coupling diodes Dh, the connection diodes Da, and the resistors Rh. However, “i” may be assigned in place of individual numbers.

The v-direction transfer part 103 includes four transfer thyristors Tv, four coupling diodes Dv, four setting thyristors S, four connection diodes Db, four connection resistors Rc, and four resistors Rv. Furthermore, the v-direction transfer part 103 includes a start diodes Dvs.

The transfer thyristors Tv are arranged in the v direction in the order of the transfer thyristors Tv1, Tv2, Tv3, and Tv4. The coupling diodes Dv are arranged in the v direction in the order of the coupling diodes Dv1, Dv2, Dv3, and Dv4. The coupling diodes Dv1, Dv2, and Dv3 are provided between the transfer thyristors Tv1 and Tv2, between the transfer thyristors Tv2 and Tv3, and between the transfer thyristors Tv3 and Tv4, respectively. The coupling diode Dv4 is provided on a side of the transfer thyristor Tv4 that is opposite the side on which the coupling diode Dv3 is provided.

The setting thyristors S are arranged in the v direction the order of the setting thyristors S1, S2, S3, and S4.

The connection diodes Db, the connection resistors Rc, and the resistors Rv are arranged in the v direction in a similar manner.

The transfer thyristors Tv, the coupling diodes Dv, the setting thyristors S, the connection diodes Db, the connection resistors Rc, and the resistors Rv are arranged in the v direction, and therefore, single-digit numbers are assigned to the transfer thyristors Tv, the coupling diodes Dv, the setting thyristors S, the connection diodes Db, the connection resistors Rc, and the resistors Rv. However, “j” may be assigned in place of individual numbers.

The laser diodes LD, the coupling diodes Dh and Dv, and the connection diodes Da and Db are two-terminal elements including an anode and a cathode.

The transfer thyristors Th and Tv, the setting thyristors S, and the driving thyristors U and B are three-terminal elements including an anode, a cathode, and a gate.

The transfer thyristors Th are an example of first transfer elements, and the transfer thyristors Tv are an example of second transfer elements. The driving thyristors U are an example of first driving elements and an example of first thyristors. The driving thyristors B are an example of second driving elements and an example of second thyristors. The setting thyristors are an example of setting elements.

Next, connection relationship of the above-mentioned elements (the laser diodes LD, the driving thyristors U and B, the transfer thyristors Th and Tv, and the like) will be explained.

As described above, a laser diode LDji, a driving thyristor Bji, and a driving thyristor Uji are connected in series and form a set. That is, the anode of the laser diode LDji is connected to the reference potential Vsub, and the cathode of the laser diode LDji is connected to the anode of the driving thyristor Bji. The cathode of the driving thyristor Bji is connected to the anode of the driving thyristor Uij. The cathode of the driving thyristor Uij is connected to an ON signal line 54 to which an ON signal Von for supplying current for light emission to the laser diode LDij is supplied.

That is, regarding all the sets each including the laser diode LDji, the driving thyristor Bji, and the driving thyristor Uji that are connected in series, the anodes of the laser diodes LDji and the cathodes of the driving thyristors Uji are connected to the reference potential Vsub and the ON signal line 54, respectively, in a parallel manner. The ON signal line 54 is an example of an ON electrode.

In the h-direction transfer part 102, the anodes of transfer thyristors Thi are connected to the reference potential Vsub. The cathodes of the transfer thyristors Th1 and Th3, which are assigned with odd numbers, are connected to a transfer signal line 52. A transfer signal φh1 is supplied from the controller 110 to the transfer signal line 52. The cathodes of the transfer thyristors Th2 and Th4, which are assigned even numbers, are connected to a transfer signal line 53. A transfer signal φh2 is supplied from the controller 110 to the transfer signal line 53.

The coupling diodes Dhi are connected in series. That is, the cathode of a coupling diode Dh is connected to the anode of a coupling diode Dh that is adjacent in a +h direction. The anodes of the coupling diodes Dhi are connected to the gates of the transfer thyristors Thi. Furthermore, the gates of the transfer thyristors Thi are connected, with the resistors Rhi therebetween, to a power supply line 51 for supplying an h-direction power supply potential Vgk1 to the h-direction transfer part 102.

The anode of the start diode Dhs is connected to the transfer signal line 53 to which a transfer signal φh2 is supplied, and the cathode of the start diode Dhs is connected to the anode of the coupling diode Dh1.

The anodes of the connection diodes Dai are connected to the gates of the transfer thyristors Thi, and the cathodes of the connection diodes Dai are connected to the gates of the driving thyristors Uji (j=1 to 4) in a parallel manner.

In the v-direction transfer part 103, the anodes of the transfer thyristors Tvj are connected to the reference potential Vsub. The cathodes of the transfer thyristors Tv1 and Tv3, which are assigned odd numbers, are connected to a transfer signal line 62. A transfer signal φv1 is supplied from the controller 110 to the transfer signal line 62. The cathodes of the transfer thyristors Tv2 and Tv4, which are assigned even numbers, are connected to a transfer signal line 63. A transfer signal φv2 is supplied from the controller 110 to the transfer signal line 63.

The coupling diodes Dvj are connected in series. That is, the cathode of a coupling diode Dv is connected to the anode of a coupling diode Dv that is adjacent in a +v direction. The anodes of the coupling diodes Dvj are connected to the gates of the transfer thyristors Tvj. Furthermore, the gates of the transfer thyristors Tvj are connected, with the resistors Rvj therebetween, to a power supply line 61 for supplying a v-direction power supply potential Vgk2 to the v-direction transfer part 103.

The anode of the start diode Dvs is connected to the transfer signal line 63 to which the transfer signal φv2 is supplied, and the cathode of the start diode Dvs is connected to the anode of the coupling diode Dv1.

The anodes of the setting thyristors Sj are connected to the reference potential Vsub, and the cathodes of the setting thyristors Sj are connected to a setting signal line 64 to which a setting signal φs is supplied from the controller 110.

The anodes of the connection diodes Dbj are connected to the gates of the transfer thyristors Tvj, and the cathodes of the connection diodes Dbj are connected to the gates of the setting thyristors Sj.

Furthermore, one end of the connection resistors Rcj are connected to the gates of the setting thyristors Sj, and the other ends of the connection resistors Rcj are connected to the gates of the driving thyristors Bji (i=1 to 4) in a parallel manner.

The configuration of the controller 110 will be explained.

The controller 110 includes an h-direction transfer signal generation part 120, a v-direction transfer signal generation part 130, a setting signal generation part 140, an ON signal generation part 150, a reference potential generation part 160, an h-direction power supply potential generation part 170, and a v-direction power supply potential generation part 180. The controller 110 is configured to be an electronic circuit. For example, the controller 110 may be configured as an integrated circuit (IC).

The h-direction transfer signal generation part 120 generates transfer signals φh1 and φh2, and supplies the transfer signals φh1 and φh2 to the transfer signal lines 52 and 53, respectively, of the light-emitting unit 100. The v-direction transfer signal generation part 130 generates transfer signals φv1 and φv2, and supplies the transfer signals φv1 and φv2 to the transfer signal lines 62 and 63, respectively, of the light-emitting unit 100.

The setting signal generation part 140 generates a setting signal φs, and supplies the setting signal φs to the setting signal line 64 of the light-emitting unit 100.

A current limit resister, which is not illustrated in FIG. 1, is provided between the h-direction transfer signal generation part 120 and the transfer signal line 52 and between the h-direction transfer signal generation part 120 and the transfer signal line 53, so that variations in the potentials of the transfer signal lines 52 and 53 do not affect the h-direction transfer signal generation part 120. The same applies to between the v-direction transfer signal generation part 130 and the transfer signal line 62, between the v-direction transfer signal generation part 130 and the transfer signal line 63, and between the setting signal generation part 140 and the setting signal line 64. That is, the potentials of the transfer signal lines 52 and 53 vary according to the operating state of the transfer thyristors Th, that is, depending on whether the transfer thyristors Th are in the ON state or the OFF state. In a similar manner, the potentials of the transfer signal lines 62 and 63 vary according to the operating state of the transfer thyristors Tv, that is, depending on whether the transfer thyristors Tv are in the ON state or the OFF state.

The above limit resistors may be provided at the light-emitting unit 100 or the controller 110. Furthermore, the above limit resistors may be provided between the light-emitting unit 100 and the controller 110.

The ON signal generation part 150 generates an ON signal Von, and supplies the ON signal Von to the ON signal line 54 of the light-emitting unit 100.

The reference potential generation part 160 generates the reference potential Vsub, and supplies the reference potential Vsub to the light-emitting unit 100.

The h-direction power supply potential generation part 170 generates the h-direction power supply potential Vgk1, and supplies the h-direction power supply potential Vgk1 to the power supply line 51 of the light-emitting unit 100. The v-direction power supply potential generation part 180 generates the v-direction power supply potential Vgk2, and supplies the v-direction power supply potential Vgk2 to the power supply line 61 of the light-emitting unit 100.

The signals generated by the h-direction transfer signal generation part 120, the v-direction transfer signal generation part 130, the setting signal generation part 140, and the ON signal generation part 150 and the potentials generated by the reference potential generation part 160, the h-direction power supply potential generation part 170, and the v-direction power supply potential generation part 180 will be described later.

The light-emitting unit 100 operates according to supplied signals and potentials.

In the explanation provided above, in the light-emitting unit 100, the laser diodes LD are arranged two-dimensionally in a 4 by 4 array. However, the arrangement of the laser diodes LD is not limited to the 4 by 4 array. Herein, i and/or j in “i by j” may be a plurality of numeric values of 4 or more. The numbers of the transfer thyristors Th and the like included in the h-direction transfer part 102 may be i. Furthermore, the numbers of the transfer thyristors Tv, the setting thyristors S, and the like included in the v-direction transfer part 103 may be j. The numbers of the transfer thyristors Th and the like may be more than i or less than i. In a similar manner, the numbers of the transfer thyristors Tv, the setting thyristors S, and the like may be more than j or less than j.

In FIG. 1, in the light-emitting unit 100, connection points connected with lines to which signals and potentials are supplied from the controller 110 are not assigned signs. The connection points are illustrated as square marks. However, in the subsequent drawings, a terminal may be provided to a signal or a potential supplied by the controller 110. For example, a connection point to which the transfer signal φh1 is supplied from the h-direction transfer signal generation part 120 will be denoted by a “φh1 terminal”.

### (Light-Emitting Unit)

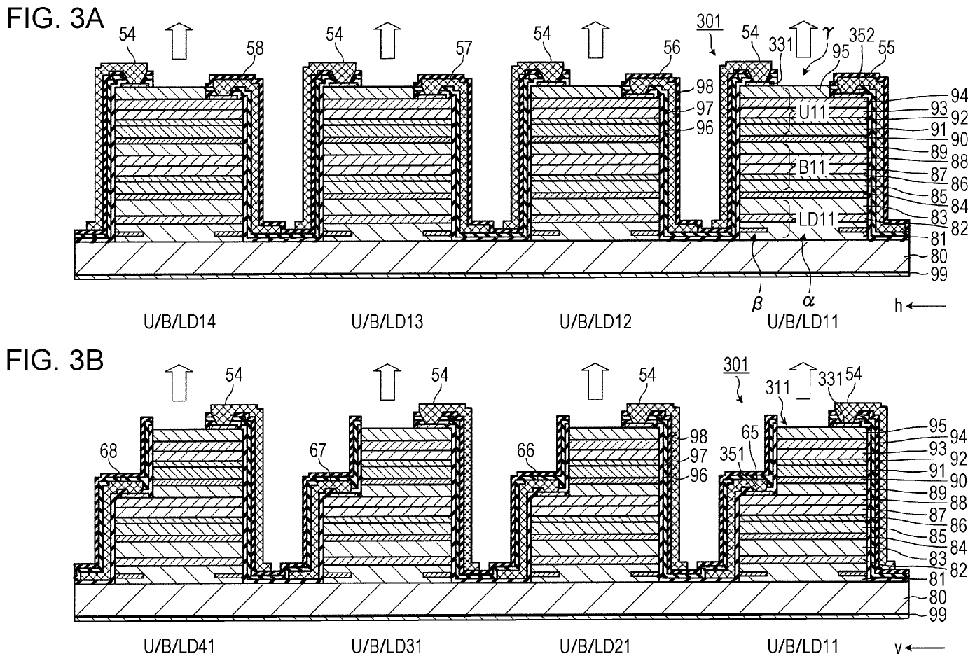

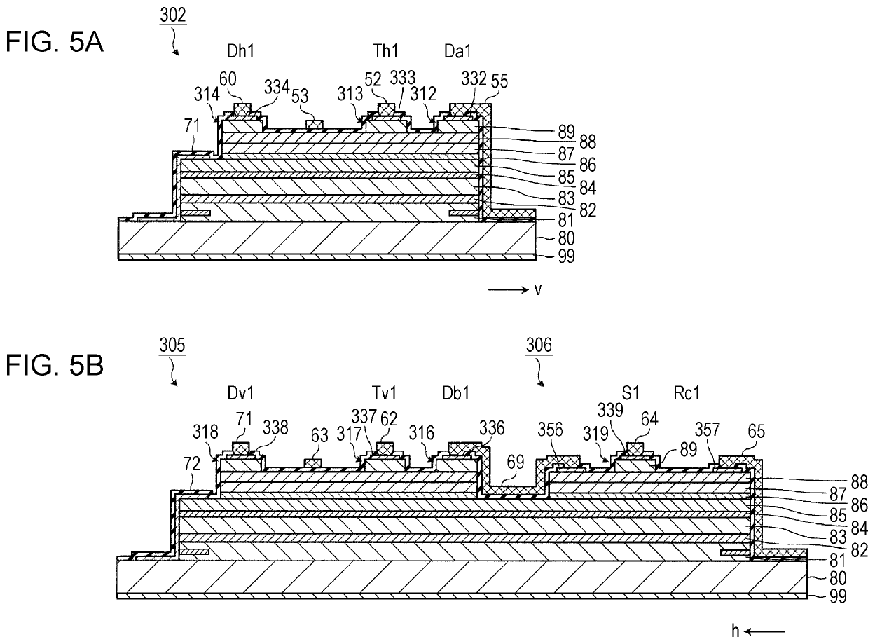

The light-emitting unit 100 is made of a semiconductor material that is capable of emitting laser light. For example, the light-emitting unit 100 is made of a GaAs compound semiconductor. As illustrated in the cross-sectional views (see FIGS. 3A, 3B, 5A, and 5B, which will be described later) of the interposer 100, which will be described later, the light-emitting unit 100 is configured as a semiconductor layer multilayer body in which a plurality of GaAs compound semiconductor layers are laminated on a substrate 80 made of p-type GaAs. The substrate 80 is set at the reference potential Vsub, which is supplied via a back electrode 99 formed on the back face of the substrate 80. First, a planer layout will be explained. The back electrode 99 is an example of a reference electrode.

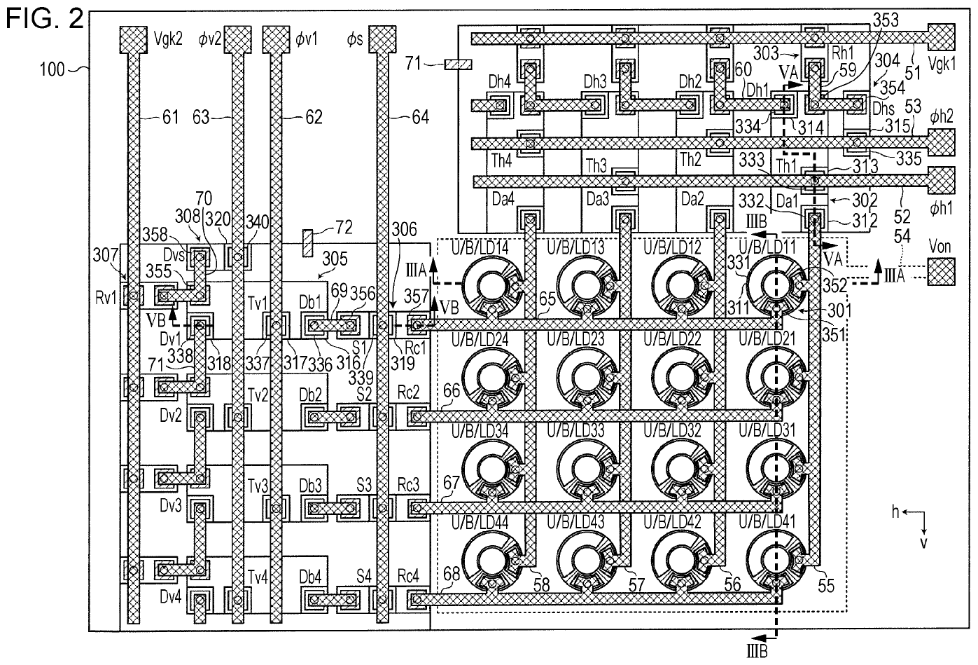

FIG. 2 is a diagram illustrating an example of a planar layout of the light-emitting unit 100.

The light-emitting unit 100 includes a plurality of islands obtained by performing inter-element isolation on the above-described semiconductor layer multilayer body by mesa etching. In this example, the planar layout of the light-emitting unit 100 will be explained with reference to islands 301 to 308 illustrated in FIG. 2.

In the island 301, the driving thyristor U11, the driving thyristor B11, and the laser diode LD11 are provided. The driving thyristor U11, the driving thyristor B11, and the laser diode LD11 are laminated and connected in series. In FIG. 2, the driving thyristor U11, the driving thyristor B11, the laser diode LD11 are represented by U/B/LD11. As described later, the laser diode LD11, the driving thyristor B11, and the driving thyristor U11 are laminated in this order from the substrate 80 side. That is, the driving thyristor U11 is arranged on an upper side, and the driving thyristor B11 is arranged on a lower side. Hereinafter, series connection of the driving thyristor U11, the driving thyristor B11, and the laser diode LD11 will be represented by driving thyristor U/driving thyristor B/laser diode LD or U/B/LD. The laminated driving thyristor U/driving thyristor B/laser diode LD is an example of a light-emitting device.

In islands similar to the island 301, sets including laser diodes LDji, driving thyristors Bji, and driving thyristors Uji, where i represents numbers 2 to 4 and j represents numbers 2 to 4, are configured.

The driving thyristor U11, the driving thyristor B11, and the laser diode LD11 may not be laminated but may be connected in series.

In the island 302, the transfer thyristor Th1, the coupling diode Dh1, and the connection diode Da1 are provided. In islands similar to the island 302, transfer thyristors Thi, coupling diodes Dhi, and connection diodes Dai, where i represents numbers 2 to 4, are provided.

In the island 303, the resistor Rh1 is provided. In islands similar to the island 303, resistors Rhi, where i represents numbers 2 to 4, are provided.

In the island 304, the start diode Dhs is provided.

In the island 305, the transfer thyristor Tv1, the coupling diode Dv1, and the connection diode Db1 are provided. In islands similar to the island 305, transfer thyristors Tvj, coupling diodes Dvj, and connection diodes Dbj, where j represents numbers 2 to 4, are provided.

In the island 306, the setting thyristor S1 and the connection resistor Rc1 are provided. In islands similar to the island 306, setting thyristors Sj and connection resistors Rcj, where j represents numbers 2 to 4, are provided.

In the island 307, the resistor Rv1 is provided. In islands similar to the island 307, resistors Rhj, where j represents numbers 2 to 4, are provided.

In the island 308, the start diode Dvs is provided.

The details of connection relationship and the like will be explained later, along with cross-sectional structures of the light-emitting element part 101, the h-direction transfer part 102, and the v-direction transfer part 103, which will be described later.

In FIG. 2, through-holes provided at connection points between wiring and islands, which will be described later, are represented by circle marks.

Next, the cross-sectional structure of the light-emitting element part 101 will be explained.

FIGS. 3A and 3B are cross-sectional views of the driving thyristor U/driving thyristor B/laser diode LD. FIG. 3A is a cross-sectional view taken along line IIIA-IIIA of FIG. 2, and FIG. 3B is a cross-sectional view taken along line IIIB-IIIB of FIG. 2. That is, in FIG. 3A, the U/B/LD11, the U/B/LD12, the U/B/LD13, and the U/B/LD14 are illustrated. In FIG. 3B, the U/B/LD11, the U/B/LD21, the U/B/LD31, and the U/B/LD41 are illustrated.

As illustrated in the cross section of the driving thyristor U11/driving thyristor B11/laser diode LD11 in FIG. 3A (in FIG. 3A, represented by U/B/LD11), a p-type anode layer (hereinafter, denoted by a p-anode layer, the same applies to the below) 81, a light-emitting layer 82, and an n-type cathode layer (n-cathode layer) 83 that configure the laser diode LD11 are laminated on the p-type GaAs substrate 80. A tunnel junction layer 84 is laminated on the n-cathode layer 83. A p-type anode layer (p-anode layer) 85, a voltage reduction layer 86, an n-type gate layer (n-gate layer) 87, a p-type gate layer (p-gate layer) 88, and an n-type cathode layer (n-cathode layer) 89 that configure the driving thyristor B11 are provided on the tunnel junction layer 84. Furthermore, a tunnel junction layer 90 is laminated on the n-cathode layer 89. A p-type anode layer (p-anode layer) 91, a voltage reduction layer 92, an n-type gate layer (n-gate layer) 93, a p-type gate layer (p-gate layer) 94, and an n-type cathode layer (n-cathode layer) 95 that configure the driving thyristor U11 are provided on the tunnel junction layer 90. The above-mentioned semiconductor layer multilayer body is subjected to isolation by mesa etching.

As described above, the laser diode LD11 includes the p-anode layer 81, the light-emitting layer 82, and the n-cathode layer 83. The driving thyristor B11 includes the p-anode layer 85, the voltage reduction layer 86, the n-gate layer 87, the p-gate layer 88, and the n-cathode layer 89. The driving thyristor U11 includes the p-anode layer 91, the voltage reduction layer 92, the n-gate layer 93, the p-gate layer 94, and the n-cathode layer 95.

The laser diode LD11 and the driving thyristor B11 are laminated with the tunnel junction layer 84 interposed therebetween, and the driving thyristor B11 and the driving thyristor U11 are laminated with the tunnel junction layer 90 interposed therebetween.

The p-anode layer 81 of a laser diode LD includes a current constriction layer. The current constricting layer is a layer for constricting a path for current flowing to the laser diode LD. As the current constriction layer, for example, a layer in which electrical resistance increases by formation of Al₂O₃ by oxidation, such as AlAs, is used. In this case, oxidation may proceed from a portion (peripheral portion) exposed by mesa etching and a central portion may not be oxidized. Thus, the central portion becomes a region in which current easily flows (current passing region α), and the oxidized peripheral portion becomes a region in which current does not easily flow (current block region β). In the peripheral portion in which defects caused by mesa etching often occur, non-light-emitting recombination easily occurs. Therefore, by setting the peripheral portion as the current block region β, electric power to be consumed by non-light-emitting recombination is reduced, and a reduction in power consumption and an improvement in light extraction efficiency may be achieved. The light extraction efficiency represents the amount of light that may be extracted per electric power.

In this example, light emitted from a laser diode LD transmits through driving thyristors B and U and is emitted out of the side opposite the substrate 80. In FIGS. 3A and 3B, emitted light is represented by arrows. A central part of the U/B/LD11 in FIG. 3A represents a light emission port γ.

As illustrated in FIGS. 3A and 3B, the ON signal line 54 is connected to an n-ohmic electrode 331 that is provided at a part on the n-cathode layer 95 of the driving thyristor U11.

Furthermore, as indicated by the U/B/LD11 in FIG. 3A, an h-gate signal line 55 is connected to a p-ohmic electrode 352 that is provided on the p-gate layer 94 of the driving thyristor U. That is, in part of the laminated semiconductor layers of the island 301, the n-cathode layer 95 is removed in the thickness direction so that the surface of the p-gate layer 94 is exposed, the p-ohmic electrode 352 is provided at the exposed p-gate layer 94, and the h-gate signal line 55 is connected to the p-ohmic electrode 352. In this example, the p-ohmic electrode 352 provided at the p-gate layer 94 may be denoted by a gate terminal or a gate of the driving thyristor U11. The p-gate layer 94 may be denoted by the gate of the driving thyristor U11. The p-ohmic electrode 352 or the p-gate layer 94 is an example of a first gate.

Furthermore, as indicated by the U/B/LD11 in FIG. 3B, a v-gate signal line 65 is connected to a p-ohmic electrode 351 that is provided on the p-gate layer 88 of the driving thyristor U. That is, in part of the laminated semiconductor layers of the island 301, the n-cathode layer 95, the p-gate layer 94, the n-gate layer 93, the voltage reduction layer 92, the p-anode layer 91, the tunnel junction layer 90, and the n-cathode layer 89 are removed in the thickness direction so that the surface of the p-gate layer 88 is exposed, the p-ohmic electrode 351 is provided at the exposed p-gate layer 88, and the v-gate signal line 65 is connected to the p-ohmic electrode 351. In this example, the p-ohmic electrode 351 provided at the p-gate layer 88 may be denoted by a gate terminal or a gate of the driving thyristor B11. The p-gate layer 88 may be denoted by the gate of the driving thyristor B11. The p-ohmic electrode 351 or the p-gate layer 88 is an example of a second gate.

Except for the connection parts described above, the island 301, the v-gate signal line 65, the h-gate signal line 55, and the ON signal line 54 are insulated from each other with insulating layers 96, 97, and 98 therebetween. That is, the surface of the island 301 is covered with the insulating layer 96. The v-gate signal line 65 is formed on the insulating layer 96. The insulating layer 96 allows insulation between the laminated semiconductor layers configuring the island 301 and the v-gate signal line 65. Next, the insulating layer 97 is provided on the v-gate signal line 65. The h-gate signal line 55 is provided on the insulating layer 97. That is, the insulating layer 97 allows insulation between the v-gate signal line 65 and the h-gate signal line 55. The insulating layer 98 is provided on the h-gate signal line 55. The ON signal line 54 is provided on the insulating layer 98. That is, the insulating layer 98 allows insulation between the h-gate signal line 55 and the ON signal line 54. Accordingly, the h-gate signal line 55, the v-gate signal line 65, and the ON signal line 54 are insulated from one another. The same applies to h-gate signal lines 56 to 58 and v-gate signal lines 66 to 68.

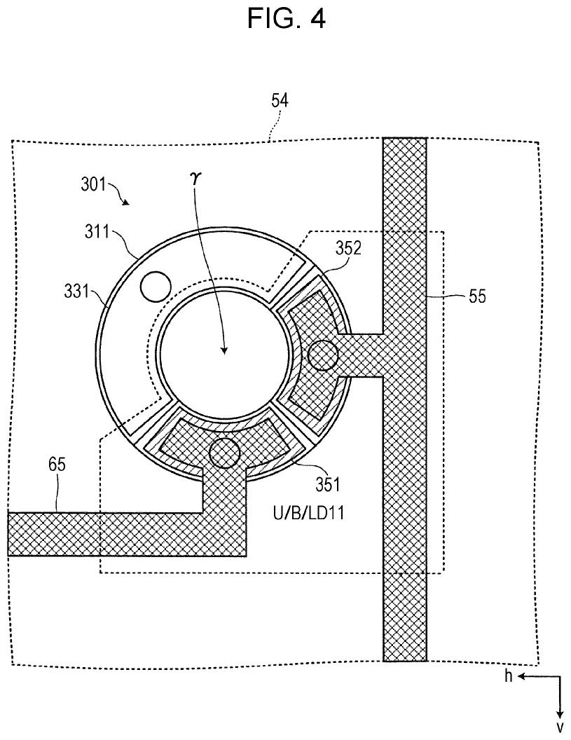

FIG. 4 is an enlarged plan view of the island 301, which includes the upper driving thyristor U11/lower driving thyristor B11/laser diode LD11. In this example, the driving thyristor U11/driving thyristor B11/laser diode LD11 will be described. However, the same applies to other driving thyristors B/driving thyristors U/laser diodes LD. In FIG. 4, the h-gate signal line 55, the v-gate signal line 65, and the ON signal line 54, in addition to the island 301, are illustrated. To clearly indicate the structure of a lower part, the ON signal line 54 is indicated by a broken line. Furthermore, in FIG. 4, although the v-gate signal line 65 does not extend in the −h direction. However, other driving thyristors B/driving thyristors U/laser diodes LD may extend also in the −h direction. In a similar manner, in FIG. 4, the h-gate signal line 55 extends in the +v direction. However, the h-gate signal line 55 may not extend in the +v direction (see FIG. 2).

As illustrated in FIG. 4, the outer shape of the surface of the island 301 is round, and a central portion of the island 301 serves as a light emission port γ of a round shape that emits light. The outer planar shape of the surface of the island 301 may not be round but may be other shapes such as a square or other polygons. The same applies to the planar shape of the light emission port γ.

In a part of the peripheral portion of the island 301, the n-cathode layer 95 is removed in the thickness direction, so that the p-gate layer 94 is exposed. The p-ohmic electrode 352, which is easily in ohmic contact with a p-type semiconductor layer, is provided on the exposed p-gate layer 94. The h-gate signal line 55 is connected to the p-ohmic electrode 352.

In a similar manner, in another part of the peripheral portion of the island 301, the n-cathode layer 95, the p-gate layer 94, the n-gate layer 93, the voltage reduction layer 92, the p-anode layer 91, the tunnel junction layer 90, and the n-cathode layer 89 are removed in the thickness direction, so that the p-gate layer 88 is exposed. The p-ohmic electrode 351, which is easily in ohmic contact with a p-type semiconductor layer, is provide on the exposed p-gate layer 88. The v-gate signal line 65 is connected to the p-ohmic electrode 351.

Furthermore, in an n-region 311 including the remaining part of the n-cathode layer 95 of the island 301, the n-ohmic electrode 331, which is easily in ohmic contact with an n-type semiconductor layer, is provided in a U shape on the n-cathode layer 95. The ON signal line 54 is connected to the n-ohmic electrode 331.

The p-ohmic electrodes 351 and 352 and the n-ohmic electrode 331 are arranged to surround the light emission port γ. The h-gate signal line 55, the v-gate signal line 65, and the ON signal line 54 are arranged not to cover the light emission port γ in such a manner that emission of light is not prevented.

As described above, the island 301, the h-gate signal line 55, the v-gate signal line 65, and the ON signal line 54 are configured such that the insulating layers 96, 97, and 98 prevent them from being short-circuited. For convenience, through-holes provided in the insulating layers 96, 97, and 98 are illustrated as having a round shape. However, the though-holes may have different shapes.

As illustrated in FIGS. 3A and 3B, light emitted from a laser diode LD transmits through a driving thyristor B and a driving thyristor U and is emitted. As another example, part of or the entire driving thyristors B and U connected to the position through which light emitted from the laser diode LD transmits (the light emission port γ) may be removed. As described above, light absorption by the driving thyristors B and U may be reduced or inhibited. Furthermore, the direction of light emitted from the laser diode LD may be set to the substrate 80 side (back face emission).

FIGS. 5A and 5B are cross-sectional views of the island 302 that includes the transfer thyristor Th1, the coupling diode Dh1, and the connection diode Da1 of the h-direction transfer part 102, the island 305 that includes the transfer thyristor Tv1, the coupling diode Dv1, and the connection diode Db1 of the v-direction transfer part 103, and the island 306 that includes the setting thyristor S1 and the connection resistor Rc1. FIG. 5A is a cross-sectional view of the island 302 taken along line VA-VA of FIG. 2, and FIG. 5B is a cross-sectional view of the island 305 and the island 306 taken along line VB-VB of FIG. 2.

First, the island 302 illustrated in FIG. 5A will be explained.

The island 302 includes the coupling diode Dh1, the transfer thyristor Th1, and the connection diode Da1 in the v direction.

The island 302 includes the p-anode layer 81, the light-emitting layer 82, and the n-cathode layer 83 that configure the laser diode LD11, the p-anode layer 85, the voltage reduction layer 86, the n-gate layer 87, the p-gate layer 88, and the n-cathode layer 89 that configure the driving thyristor B11, and the tunnel junction layer 84 provided between the n-cathode layer 83 and the p-anode layer 85 in the island 301. That is, the island 302 includes none of the p-anode layer 91, the voltage reduction layer 92, the n-gate layer 93, the p-gate layer 94, and the n-cathode layer 95 that configure the driving thyristor U nor the tunnel junction layer 90 that is provided between the n-cathode layer 89 and the p-anode layer 91 in the island 301.

That is, in the semiconductor layer multilayer body, the tunnel junction layer 90, the p-anode layer 91, the voltage reduction layer 92, the n-gate layer 93, the p-gate layer 94, and the n-cathode layer 95 are removed.

In addition, the substrate 80 is exposed around the island 302.

The transfer thyristor Th1 includes the n-cathode layer 89, the p-gate layer 88, the n-gate layer 87, the voltage reduction layer 86, and the p-anode layer 85. That is, the n-cathode layer 89 serves as the cathode, the p-gate layer 88 servers as the gate, and the p-anode layer 85 serves as the anode. An n-ohmic electrode 333 that is provided on an n-region 313 formed of the n-cathode layer 89 serves as a cathode terminal and is connected to the transfer signal line 52. A p-ohmic electrode 353 (see FIG. 2) that is provided on the p-gate layer 88, which is exposed by removal of the n-cathode layer 89, serves as a gate terminal and is connected to one terminal (a p-ohmic electrode assigned no sign illustrated in FIG. 2) provided on the island 303 and to a p-ohmic electrode 354, which serves as an anode terminal of the start diode Dhs.

Furthermore, as part of the island 302, the n-cathode layer 89, the p-gate layer 88, the n-gate layer 87, and the voltage reduction layer 86 are removed in the thick direction, so that the p-anode layer 85 is exposed. The exposed p-anode layer 85 and the exposed substrate 80 are connected by a p-ohmic electrode 71. That is, the reference potential Vsub is applied to the p-anode layer 85, which serves as the anode of the transfer thyristor Th1. The p-anode layer 81, the light-emitting layer 82, and the n-cathode layer 83 configuring the laser diode LD are short-circuited by the p-ohmic electrode 71 and thus do not emit light.

The n-ohmic electrode 333 serving as the cathode terminal and the p-ohmic electrode 353 serving as the gate terminal may not be provided. Thus, in the transfer thyristor Th, the n-cathode layer 89, the p-gate layer 88, and the p-anode layer 85 may be denoted by the cathode, the gate, and the anode, respectively. The same applies to the transfer thyristor Tv and the setting thyristor S, which will be described later.

In FIG. 5A, the p-ohmic electrode 71 is provided in a portion adjacent to the coupling diode Dh1. However, as illustrated in FIG. 2, in the islands 302 and 303, islands similar to the islands 302 and 303, and the island 304, mesa etching may be performed for the n-cathode layer 89, the p-gate layer 88, the n-gate layer 87, and the voltage reduction layer 86 in the thickness direction, so that element isolation between islands is performed, and the p-anode layer 85, the tunnel junction layer 84, the n-cathode layer 83, the light-emitting layer 82, and the p-anode layer 81 may be maintained. In this case, as illustrated in FIG. 2, the p-ohmic electrode 71, which allows connection between the substrate 80 and the p-anode layer 85, is provided in common. That is, a region where the p-ohmic electrode 71 is provided decreases.

The coupling diode Dh1 includes the n-cathode layer 89 and the p-gate layer 88. That is, in the coupling diode Dh1, an n-ohmic electrode 334 that is provided on an n-region 314 formed of the n-cathode layer 89 serves as a cathode terminal and is connected to wiring 60. The wiring 60 is connected to the gate terminal of the transfer thyristor Th2 (a gate terminal similar to the p-ohmic electrode 353 of the island 302) in an adjacent island similar to the island 302 (see FIG. 2).

In contrast, in the coupling diode Dh1, the p-ohmic electrode 353 provided on the p-gate layer 88 serves as the anode terminal and is connected to one terminal of the resistor Rh1 (a p-ohmic electrode assigned no sign illustrated in FIG. 2) provided on the island 303. The p-gate layer 88 serving as the anode of the coupling diode Dh1 is the same as the p-gate layer 88 of the transfer thyristor Th1. That is, the anode of the coupling diode Dh1 and the gate of the transfer thyristor Th1 are connected with the p-gate layer 88 interposed therebetween.

The n-ohmic electrode 334 serving as the cathode terminal and the p-ohmic electrode 353 serving as the anode terminal may not be provided. Thus, in the coupling diode Dh, the n-cathode layer 89 and the p-gate layer 88 may be denoted by the cathode and the anode, respectively. The same applies to the coupling diode Dv and the connection diodes Da and Db described later.

As with the coupling diode Dh1, the connection diode Da1 includes the n-cathode layer 89 and the p-gate layer 88. That is, an n-ohmic electrode 332 that is provided on an n-region 312 formed of the n-cathode layer 89 serves as an anode terminal and is connected to the h-gate signal line 55. In contrast, the p-gate layer 88, which serves as the anode of the connection diode Da1, is the same as the p-gate layer 88 of the transfer thyristor Th1 and is connected to the anode of the connection diode Da1 and the gate of the transfer thyristor Th1 with the p-gate layer 88 interposed therebetween. The h-gate signal line 55 is connected to the gate of the driving thyristor U11 provided on the island 301 (see FIG. 3A).

Although not illustrated in FIG. 5A, in the island 303 in which the resistor Rh1 is provided, the p-gate layer 88 between a pair of p-ohmic electrodes (no signs) provided on the p-gate layer 88 exposed by removal of the n-cathode layer 89 is used as a resistor. One of the p-ohmic electrodes is connected to the p-ohmic electrode 353, which is the gate of the transfer thyristor Th1 provided in the island 302. The other one of the p-ohmic electrodes is connected to the power supply line 51.

Similarly, although not illustrated in FIG. 5A, the same applies to the island 304 in which the start diode Dhs is provided. That is, an n-ohmic electrode 335 that is provided on an n-region 315 formed of the n-cathode layer 89 is connected to the transfer signal line 53. A p-ohmic electrode 354 that is provided on the p-gate layer 88 exposed by removal of the n-cathode layer 89 is connected to wiring 59. The wiring 59 is connected to the p-ohmic electrode 353, which is the gate of the transfer thyristor Th1 provided on the island 302.

Next, the islands 305 and 306 illustrated in FIG. 5B will be described.

The island 305 includes the connection diode Db1, the transfer thyristor Tv1, and the coupling diode Dv1 in the h direction. The configuration of the island 305 is similar to that of the island 302, and detailed explanation for the configuration of the island 305 will be omitted. The configuration of the island 307 in which the resistor Rv1 is provided and the configuration of the island 308 in which the start diode Dvs is provided are also similar to the configuration of the island 302, and therefore, detailed explanation for the configuration of the island 307 and the configuration of the island 308 will be omitted.

The island 306 includes the connection resistor Rc1 and the setting thyristor S1 in the h direction. As with the transfer thyristor Th1, the setting thyristor S1 includes the n-cathode layer 89, the p-gate layer 88, the n-gate layer 87, the voltage reduction layer 86, and the p-anode layer 85. That is, the n-cathode layer 89, the p-gate layer 88, and the p-anode layer 85 serve as the cathode, the gate, and the anode, respectively. An n-ohmic electrode 339 that is provided on an n-region 319 formed of the n-cathode layer 89 serves as a cathode terminal and is connected to the setting signal line 64. A p-ohmic electrode 356 that is provided on the p-gate layer 88 exposed by removal of the n-cathode layer 89 serves as a gate terminal and is connected to wiring 69. The wiring 69 is connected to an n-ohmic electrode 336, which is a cathode terminal provided on an n-region 316 formed of the n-cathode layer 89 of the connection diode Db1 on the island 305. That is, the cathode of the connection diode Db1 and the gate of the setting thyristor S1 are connected by the wiring 69.

Furthermore, in the island 306, a p-ohmic electrode 357 that is provided on the p-gate layer 88 exposed by removal of the n-cathode layer 89 is connected to the v-gate signal line 65. That is, in the island 306, a part of the p-gate layer 88 from a region corresponding to the setting thyristor S1 to the p-ohmic electrode 357 functions as a resistor and configures the connection resistor Rc1.

As part of the island 305, the n-cathode layer 89, the p-gate layer 88, the n-gate layer 87, and the voltage reduction layer 86 are removed in the thickness direction, so that the p-anode layer 85 is exposed. The exposed p-anode layer 85 and the exposed substrate 80 are connected by a p-ohmic electrode 72. The island 305 and the island 306 are subjected to element isolation by removal of the n-cathode layer 89, the p-gate layer 88, the n-gate layer 87, and the voltage reduction layer 86 in the thickness direction. That is, the p-anode layer 85 is shared between the island 305 and the island 306. Therefore, the reference potential Vsub is supplied to the p-anode layer 85 of the islands 305 and 306. The p-anode layer 81, the light-emitting layer 82, and the n-cathode layer 83 that configure the laser diode LD are short-circuited by the p-ohmic electrode 72 and thus do not emit light.

The same applies to other islands.

As illustrated in FIG. 2, in the islands 305, 306, and 307, islands similar to the islands 305, 306, and 307, and the island 308, the n-cathode layer 89, the p-gate layer 88, the n-gate layer 87, and the voltage reduction layer 86 may be removed in the thickness direction so that element isolation between islands is performed, and the p-anode layer 85, the tunnel junction layer 84, the n-cathode layer 83, the light-emitting layer 82, and the p-anode layer 81 may be maintained. In this case, as illustrated in FIG. 2, the p-ohmic electrode 72 that allows connection between the substrate 80 and the p-anode layer 85 may be provided in common. The p-ohmic electrode 71 and the p-ohmic electrode 72 may be provided in common.

As described above, a semiconductor layer multilayer body in which a plurality of semiconductor layers are laminated is separated by mesa etching, and some layers are removed. Accordingly, the light-emitting unit 100 whose equivalent circuit is illustrated in FIG. 1 is configured.

### <Thyristor>

Next, a basic operation of thyristors (the transfer thyristors Th and Tv, the setting thyristors S, and the driving thyristors U and B) will be described. As illustrated in FIG. 5A, the p-anode layer 85 of the transfer thyristor Th1 in the island 302 is connected to the substrate 80 and set at the reference potential Vsub. Therefore, the transfer thyristor Th1 will be explained as an example of a thyristor.

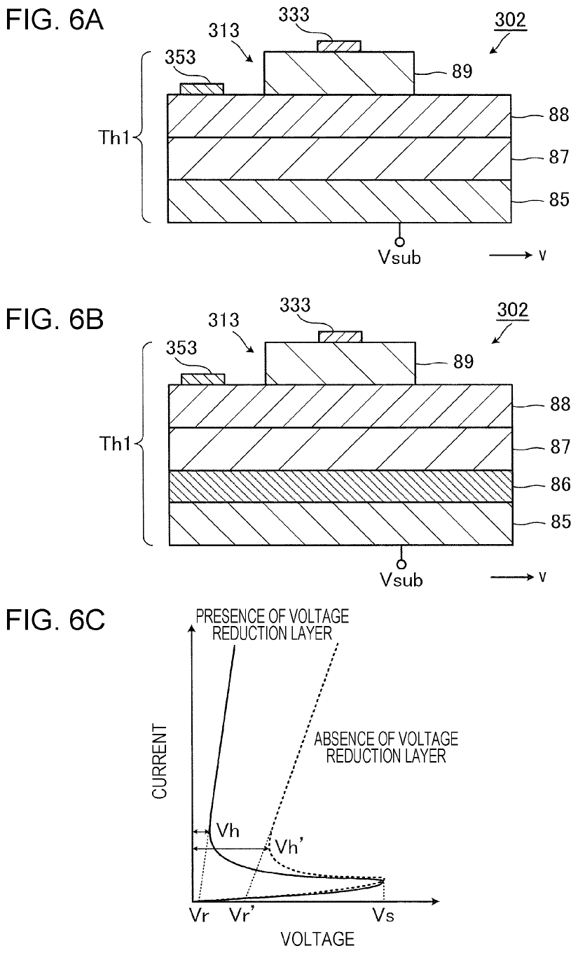

FIGS. 6A to 6C are diagrams for explaining an operation of a thyristor. FIG. 6A illustrates a case where the voltage reduction layer 86 is not provided, FIG. 6B illustrates a case where the voltage reduction layer 86 is provided, and FIG. 6C illustrates thyristor characteristics. In FIG. 6C, voltage is indicated as an absolute value. Furthermore, in FIG. 6C, the thyristor characteristics for the case where the voltage reduction layer 86 is not provided represent “absence of the voltage reduction layer”, and the thyristor characteristics for the case where the voltage reduction layer 86 is provided represent “presence of the voltage reduction layer.”

As illustrated in FIG. 5A, the transfer thyristor Th1 includes the p-anode layer 85, the voltage reduction layer 86, the n-gate layer 87, the p-gate layer 88, and the n-cathode layer 89 that are laminated. The reference potential Vsub is supplied to the p-anode layer 85.

A thyristor that does not include the voltage reduction layer 86 includes the p-anode layer 85, the n-gate layer 87, the p-gate layer 88, and the n-cathode layer 89 that are laminated, as illustrated in FIG. 6A. The n-cathode layer 89 except for the n-region 313 is removed, so that the p-gate layer 88 is exposed. The n-ohmic electrode 333 is provided as a cathode terminal on the n-region 313 of the n-cathode layer 89, and the p-ohmic electrode 353 is provided as a gate terminal on the p-gate layer 88.

In contrast, a thyristor that includes the voltage reduction layer 86 illustrated in FIG. 6B includes the voltage reduction layer 86 between the p-anode layer 85 and the n-gate layer 87.

As described above, a thyristor is a semiconductor element that includes three terminals; anode; cathode; and gate. For example, a thyristor includes p-type semiconductor layers (the p-anode layer 85, the p-gate layer 88, etc.) and n-type semiconductor layers (the n-gate layer 87, the n-cathode layer 89, etc.), such as GaAs, GaAlAs, AlAs, and the like, that are laminated. That is, a thyristor has a pnpn structure. In this example, explanation will be provided in which a forward potential (diffusion potential) Vd of pn junction including a p-type semiconductor layer and an n-type semiconductor layer is, for example, 1.5 V.

First, an operation of a thyristor that does not include the voltage reduction layer 86 illustrated in FIG. 6A will be described.

Explanation will be provided in which, for example, the reference potential Vsub of the p-anode layer 85 is set to 0 V as a potential of high level (hereinafter, denoted by “H”), and the h-direction power supply potential Vgk1 supplied by the h-direction power supply potential generation part 170 in the controller 110 is set to −3.3 V as a potential of low level (hereinafter, denoted by “L”). These potentials may be denoted by “H (0 V)” and “L (−3.3 V)”. As illustrated in FIG. 1, the power supply line 51 to which the h-direction power supply potential Vgk1 is supplied is connected to the gate of the transfer thyristor Th1 with the resistor Rh1 interposed therebetween.

A thyristor in the OFF state in which no current flows between the anode and cathode enters the ON state (is turned ON) when a potential (negative potential with a large absolute value) lower than a threshold voltage (Vs in FIG. 6C) is applied to the cathode. The threshold voltage of the thyristor is obtained by subtracting the forward potential Vd (1.5 V) of pn junction from the potential of the gate.

When the thyristor enters the ON state, the gate of the thyristor reaches a potential close to the potential of the anode. The potential of the anode is 0 V, and therefore, the potential of the gate becomes 0 V. Furthermore, the cathode of the thyristor in the ON state reaches a potential (the absolute value is represented by a holding voltage) close to a value obtained by subtracting the forward potential Vd (1.5 V) of pn junction from the potential of the anode. The potential of the anode is 0 V, and therefore, the potential of the cathode of the thyristor in the ON state becomes a value (negative potential whose absolute value is larger than 1.5 V) close to −1.5 V (Vh′ in FIG. 6C). The holding voltage is 1.5 V.

A potential (negative potential with a large absolute value) lower than the potential necessary for the thyristor to be maintained in the ON state is continuously applied to the cathode of the thyristor, and a current that allows the thyristor to maintain the ON state (holding current) is supplied. Accordingly, the ON state is maintained.

In contrast, when the cathode of the thyristor in the ON state reaches a potential (negative potential with a small absolute value, 0 V, or positive potential) higher than the potential (close to −1.5 V mentioned above) necessary for the thyristor to be maintained in the ON state, the thyristor enters the OFF state (is turned OFF).

Next, an operation of a thyristor that includes the voltage reduction layer 86 illustrated in FIG. 6B will be described.

A rising voltage (Vr in FIG. 6C) of a thyristor is determined according to energy (band gap energy) of the smallest band gap in the semiconductor layer multilayer body configuring the thyristor. The rising voltage Vr of the thyristor represents voltage at the time when current in the thyristor in the ON state is extrapolated to the voltage axis, as illustrated in FIG. 6C.

The voltage reduction layer 86 is a layer that has a band gap energy smaller than that of the p-anode layer 85, the n-gate layer 87, the p-gate layer 88, and the n-cathode layer 89. Therefore, the rising voltage Vr of the thyristor that includes the voltage reduction layer 86 is lower than a rising voltage Vr′ of the thyristor that does not include the voltage reduction layer 86 illustrated in FIG. 6A. Furthermore, for example, the voltage reduction layer 86 is a layer that has a band gap smaller than that of the light-emitting layer 82.

In this example, thyristors (transfer thyristors Th and Tv, setting thyristors S, and driving thyristors B and U) are not used as light-emitting elements but are provided to drive light-emitting elements such as laser diodes LD and the like. Therefore, band gap is set irrespective of the light-emitting wavelength of a light-emitting element such as a laser diode LD. Thus, when the voltage reduction layer 86, which has a band gap smaller than that of the light-emitting layer 82, is provided, the rising voltage of a thyristor may be reduced from Vr′ to Vr (Vr′>Vr). Although the rising voltages Vr and Vr′ of thyristors have been described above, the same applies to holding voltages (Vh and Vh′ in FIG. 6C), which are voltages for allowing thyristors to maintain the ON state. In this example, the holding voltage in the case where the voltage reduction layer 86 is not provided is 1.5 V (Vh′), whereas, the holding voltage in the case where the voltage reduction layer 86 is provided is 0.8 V (Vh).

In contrast, the threshold voltage of a thyristor (Vs in FIG. 6C) is determined according to a depletion layer among semiconductor layers with reverse bias. Therefore, the influence of provision of the voltage reduction layer 86 on the threshold voltage of a thyristor is small. In this example, the threshold voltage is the same regardless of whether or not the voltage reduction layer 86 is provided. The threshold voltage may be referred to as a switching voltage.

The operation of the thyristor explained above is an operation in the case where potential is applied to the cathode in a state in which both the anode and the cathode are in “H” state. At this time, a potential (absolute value) obtained by adding the forward potential Vd to the potential of the gate is applied to the cathode, the thyristor is turned ON and enters the ON state. Then, the holding voltage is obtained between the anode and cathode of the thyristor. In the case where the voltage reduction layer 86 is provided, the absolute value is 0.8 V.

In contrast, in the case where a forward bias state is entered between the cathode and the gate and current flows, when the holding voltage (absolute value) or more is applied between the anode and the cathode, the thyristor is shifted from the OFF state to the ON state. That is, forward bias is obtained between the base and emitter of a parasitic bipolar transistor configuring the thyristor, in this case, an npn bipolar transistor. Thus, when a potential equal to or more than the holding voltage is applied between the anode and the cathode, the thyristor enters the ON state. The thyristor that includes the voltage reduction layer 86 enters the ON state when a voltage with an absolute value of 0.8 V or more is applied.

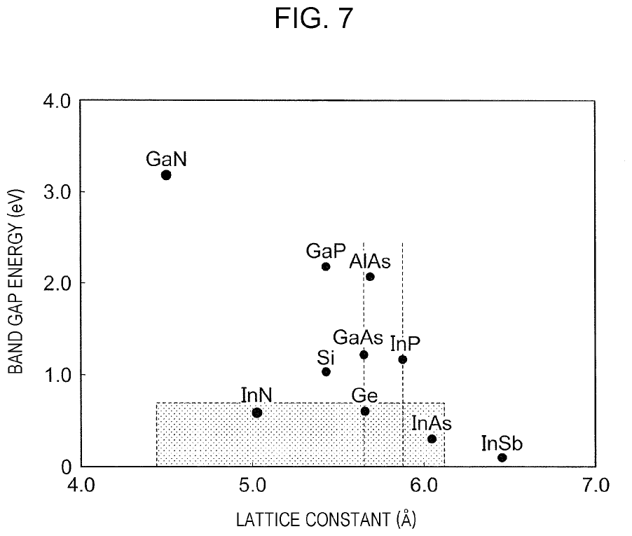

FIG. 7 is a diagram for explaining band gap energy of a material forming a semiconductor layer multilayer body.

The lattice constant of GaAs is about 5.65 Å. The lattice constant of AlAs is about 5.66 Å. Therefore, a material having a lattice constant close to the above lattice constants may achieve epitaxial growth with respect to a GaAs substrate. For example, AlGaAs or Ge, which is a compound of GaAs and AlAs, may achieve epitaxial growth with respect to a GaAs substrate.

Furthermore, the lattice constant of InP is about 5.87 Å. A material having a lattice constant close to the above lattice constant may achieve epitaxial growth with respect to an InP substrate.

Furthermore, although depending on the growth surface, the lattice constant of GaN is 3.19 Å for surface a and 5.17 Å for surface c. A material having a lattice constant close to the above lattice constant may achieve epitaxial growth with respect to a GaN substrate.

A material for which the rising voltage of a thyristor is smaller than that for GaAs, InP, and GaN is a material with a band gap energy smaller than that of the above materials. For example, such a material is within a range indicated by halftone dots in FIG. 7. That is, in the case where a material within the range indicated by the halftone dots is used as a layer configuring a thyristor, the rising voltage of the thyristor (Vr illustrated in FIG. 6C) is equal to band gap energy of the material within the region indicated by the halftone dots.

For example, band gap energy of GaAs is about 1.43 eV. Therefore, the rising voltage of the thyristor that does not include the voltage reduction layer 86 (Vr′ illustrated in FIG. 6C) is about 1.43 V. However, the material within the range indicated by the halftone dots may be used for a layer configuring the thyristor or may be included, so that the rising voltage (Vr illustrated in FIG. 6C) of the thyristor may be set to more than 0 V and less than 1.43 V (0 V<Vr<1.43 V).

Accordingly, power consumption in the case where the thyristor is in the ON state is reduced.

As a material within the range indicated by the halftone dots, Ge whose band gap energy with respect to GaAs is about 0.67 eV may be used. Furthermore, InAs whose band gap energy with respect to InP is about 0.36 eV may be used. Furthermore, a material whose band gap energy in a compound of GaAs and InP, a compound of InN and InSb, a compound of InN and InAs, or the like with respect to a GaAs substrate or an InP substrate is small may be used. In particular, mixed compounds with a base of GaInNAs are suitable. Such mixed compounds may include Al, Ga, As, P, Sb, and the like. Furthermore, GaNp may serve as the voltage reduction layer 86 with respect to GaN. In addition, (1) an InN layer, an InGaN layer, or a GaNAs layer by metamorphic growth or the like, (2) quantum dots including InN, InGaN, InNAs, InNSb, or GaNAs, or (3) an InAsSb layer or the like corresponding to twice the lattice constant of GaN (surface a), may be introduced as the voltage reduction layer 86. These materials may include Al, Ga, N, As, P, Sb, and the like.

That is, the voltage reduction layer 86 reduces the rising voltage while maintaining the switching voltage Vs of the thyristor. Accordingly, the holding voltage applied to the thyristor in the ON state is reduced, and power consumption is thus reduced. Furthermore, the threshold voltage (Vs in FIG. 6C) of the thyristor is set to a desired value by adjusting materials, impurity concentration, and the like of the p-anode layer 85, the n-gate layer 87, the p-gate layer 88, and the n-cathode layer 89. However, the threshold voltage may vary according to the position into which the voltage reduction layer 86 is inserted.

In FIG. 6B, an example in which the number of voltage reduction layers 86 provided is one is illustrated. However, a plurality of voltage reduction layers 86 may be provided. For example, the voltage reduction layer 86 may be provided between the p-anode layer 85 and the n-gate layer 87, between the n-gate layer 87 and the p-gate layer 88, and between the p-gate layer 88 and the n-cathode layer 89 or may be additionally provided in the n-gate layer 87 and in the p-gate layer 88. Alternatively, the voltage reduction layer 86 may be provided in two or three of the p-anode layer 85, the n-gate layer 87, the p-gate layer 88, and the n-cathode layer 89. The conductive type of these voltage reduction layers may be set to fit an anode layer, a cathode layer, or a gate layer including a voltage reduction layer or may be of i type.

Compared to GaAs, InP, and the like, a material used for the voltage reduction layer 86 is difficult to grow and has a low quality. Therefore, a defect is likely to occur inside the voltage reduction layer 86, and the defect extends to the inside of a semiconductor such as GaAs growing above the voltage reduction layer 86.

As described above, light-emitting characteristics of a light-emitting element such as a laser diode LD is easily affected by a defect included in a semiconductor layer. In contrast, thyristors (transfer thyristors Th and Tv, setting thyristors S, and driving thyristors B and U) only need to be turned ON so that current may be supplied to the laser diode LD. Therefore, if a thyristor that includes the voltage reduction layer 86 is not used as a light-emitting layer but is used for voltage reduction, a defect may be included in a semiconductor layer forming the thyristor.

Thus, the laser diode LD and a structure similar to that of the laser diode LD may be provided on the substrate 80, and the transfer thyristors Th and Tv, the setting thyristor S, and the driving thyristors B and U including the voltage reduction layer 86 may be provided on such a structure. Accordingly, generation of a detect in the laser diode LD may be suppressed, and light-emitting characteristics may be less affected by the defect. Furthermore, the transfer thyristors Th and Tv, the setting thyristor S, and the driving thyristors B and U may be laminated in a monolithic manner.

### <Lamination Structure of Laser Diode and Driving Thyristors>

Next, the structure of the driving thyristor U/driving thyristor B/laser diode LD illustrated in FIGS. 3A and 3B will be explained. As illustrated in FIG. 3A, the laser diode LD and the driving thyristor B are laminated with the tunnel junction layer 84 interposed therebetween and are connected in series. Furthermore, the driving thyristor B and the driving thyristor U are laminated with the tunnel junction layer 90 interposed therebetween and are connected in series.

The tunnel junction layers 84 and 90 will be explained below with reference to the tunnel junction layer 84 between the laser diode LD and the driving thyristor B.

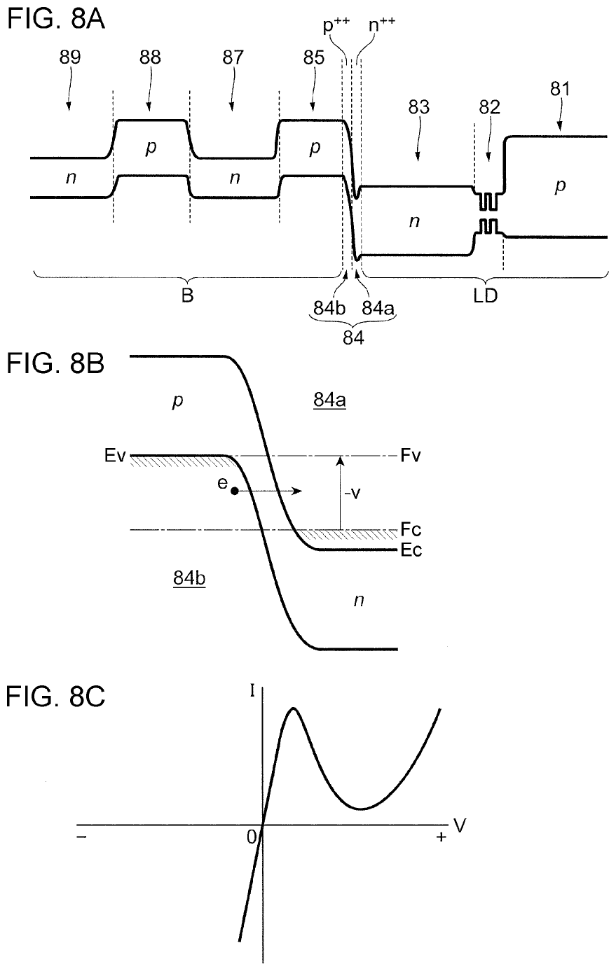

FIGS. 8A, 8B, and 8C are diagrams for further explaining the lamination structure of the laser diode LD and the lower driving thyristor B. FIG. 8A is a schematic energy band diagram of the lamination structure of the laser diode LD and the driving thyristor B, FIG. 8B is an energy band diagram in the case where the tunnel junction layer 84 is in a reverse bias state, and FIG. 8C illustrates current-voltage characteristics of the tunnel junction layer 84. Description of the voltage reduction layer 86 will be omitted.

As illustrated in the energy band diagram of FIG. 8A, the tunnel junction layer 84 is junction of an n⁺⁺ layer 84a in which an n-type impurity is added at high concentration and a p⁺⁺ layer 84b in which a p-type impurity is added at high concentration. When voltage is applied such that each of the laser diode LD and the driving thyristor B becomes forward biased, reverse bias is obtained between the n⁺⁺ layer 84a and the p⁺⁺ layer 84b configuring the tunnel junction layer 84.

However, since the tunnel junction layer 84 is junction of the n⁺⁺ layer 84a in which an n-type impurity is added at high concentration and the p⁺⁺ layer 84b in which a p-type impurity is added at high concentration, the width of a depletion region is narrow. Therefore, when a forward bias is applied, electrons tunnel from a conduction band on the n⁺⁺ layer 84a side to a valence band on the p⁺⁺ layer 84b side. At this time, negative resistance characteristics appear (see a forward bias side (+V) in FIG. 8C).

In contrast, as illustrated in FIG. 8B, when a reverse bias (−V) is applied to the tunnel junction layer 84, the potential Ev of the valence band on the p⁺⁺ layer 84b side becomes higher than the potential Ec of the conduction band on the n⁺⁺ layer 84a side. Then, electrons tunnel from the valence band of the p⁺⁺ layer 84b side to the conduction band on the n⁺⁺ layer 84a side. As the reverse bias voltage (− V) increases, electrons tunnel more easily. That is, in the tunnel junction layer 84 (tunnel junction), as indicated by the reverse bias side (−V) in FIG. 8C, current flows more easily with a larger reverse bias.

Thus, as illustrated in FIG. 8A, when the driving thyristor B is turned ON, even if the tunnel junction layer 84 is reverse biased, current flows between the laser diode LD and the driving thyristor B. The same applies to the tunnel junction layer 90. To allow current to flow in the laser diode LD, the driving thyristor also needs to be turned ON. Hereinafter, explanation will be provided on the assumption that there is no potential drop in the tunnel junction layers 84 and 90.

In place of the tunnel junction layer 84, a III-V compound layer that has a metallic conductivity and achieves epitaxial growth with respect to a III-V compound semiconductor layer may be used. Band gap energy of InNAs, which will be explained as an example of a material of a III-V compound layer with a metallic conductivity, is negative, for example, in the case where the composition ratio x of InN is within a range from about 0.1 to about 0.8. Furthermore, band gap energy of InNSb is negative, for example, in the case where the composition ratio x of InN is within a range from about 0.2 to about 0.75. Negative band gap energy represents no band gap. Thus, conduction characteristics (conductivity characteristics) similar to those of metal are exhibited. That is, metallic conduction characteristics (conductivity) represent that current flows in the case where there is a potential gradient, as with metal.

The lattice constant of a III-V compound (semiconductor) such as GaAs or InP is within a range from 5.6 Å to 5.9 Å. This lattice constant is close to the lattice constant of Si, which is about 5.43 Å, and the lattice constant of Ge, which is about 5.66 Å.

In contrast, the lattice constant of InN, which is a III-V compound, is about 5.0 Å with a zinc blende structure, and the lattice constant of InAs is about 6.06 Å. Therefore, the lattice constant of InNAs, which is a compound of InN and InAs, may be a value close to the range from 5.6 Å to 5.9 Å for GaAs or the like.

Furthermore, the lattice constant of InSb, which is a III-V compound, is about 6.48 Å. Therefore, since the lattice constant of InN is about 5.0 Å, the lattice constant of InNSb, which is a compound of InSb and InN, may be a value close to the range from 5.6 Å to 5.9 Å for GaAs or the like.

That is, InNAs and InNSb may achieve epitaxial growth in a monolithic manner with respect to a III-V compound (semiconductor) layer such as GaAs. Furthermore, a layer of a III-V compound (semiconductor) such as GaAs may be laminated in a monolithic manner on a layer of InNAs or InNSb by epitaxial growth.

Therefore, with a structure in which the laser diode LD and the driving thyristor B are laminated such that they are connected in series with a III-V compound layer with a metallic conductivity, in place of the tunnel junction layer 84, interposed therebetween, a situation in which the n-cathode layer 83 of the laser diode and the p-anode layer 85 of the driving thyristor B is reverse biased may be suppressed.

### (Configuration of Semiconductor Layer Multilayer Body)

The semiconductor layer multilayer body is configured, as described above, such that the p-anode layer 81, the light-emitting layer 82, the n-cathode layer 83, the tunnel junction layer 84, the p-anode layer 85, the voltage reduction layer 86, the n-gate layer 87, the p-gate layer 88, the n-cathode layer 89, the tunnel junction layer 90, the p-anode layer 91, the voltage reduction layer 92, the n-gate layer 93, the p-gate layer 94, and the n-cathode layer 95 are laminated on the substrate 80.

As described above, p-type GaAs is described as an example of the substrate 80. However, the substrate 80 may be n-type GaAs or intrinsic (i) GaAs to which no impurities are added. Furthermore, the substrate 80 may be InP, GaN, InAs, a semiconductor substrate made of other III-V materials or II-VI materials, sapphire, Si, Ge, or the like. If a substrate made of a different material is used, as a material laminated in a monolithic manner on the substrate, a material that substantially matches the lattice constant of the substrate (including a strain structure, a strain relaxation layer, and metamorphic growth) is used. For example, InAs, InAsSb, GaInAsSb, or the like is used on an InAs substrate, InP, InGaAsP, or the like is used on an InP substrate, GaN, AlGaN, or InGaN is used for a GaN substrate or a sapphire substrate, and Si, SiGe, GaP, or the like is used for an Si substrate. However, in the case where the substrate 80 has electrical insulation characteristics, wiring for supplying the reference potential Vsub needs to be provided separately. Furthermore, in the case where a semiconductor layer multilayer body except for the substrate 80 is attached to another supporting substrate and the semiconductor layer multilayer body is provided on the supporting substrate, the lattice constant of the substrate 80 does not need to match the lattice constant of the supporting substrate.

The p-anode layer 81 is configured such that a lower p layer, a current constriction layer, and an upper p layer are laminated in order. The lower p layer and the upper p layer are made of, for example, p-type Al_{0.9}GaAs with an impurity concentration of 5×10¹⁷/cm³. The Al composition may be varied within a range from 0 to 1.

The current constriction layer is made of, for example, AlAs or p-type AlGaAs with a high impurity concentration. When Al oxidizes and Al₂O₃ is formed, electrical resistance may increase and a current block region β may be formed. By implanting hydrogen ion (H⁺) to a semiconductor layer such as GaAs, AlGaAs, or the like, the current block region β may be formed (H⁺ ion implantation).

The light-emitting layer 82 has a quantum well composition in which a well layer and a barrier layer are laminated alternately. The well layer is made of, for example, GaAs, AlGaAs, InGaAs, GaAsP, AlGaInP, GaInAsP, GaInP, or the like, and the barrier layer is made of, for example, AlGaAs, GaAs, GaInp, GaInAsP, or the like. The light-emitting layer 82 may have a quantum line (quantum wire) or a quantum box (quantum dots).

The tunnel junction layer 84 is configured by junction of the n⁺⁺ layer 84a in which an n-type impurity is added with high concentration and the p⁺⁺ layer 84b in which an n-type impurity is added with high concentration (see FIG. 8A). For example, the n⁺⁺ layer 84a and the p⁺⁺ layer 84b contain impurities with a high concentration of 1×10²⁰/cm³. The impurity concentration for normal junction ranges from the order of 10¹⁷/cm³ to the order of 10¹⁸/cm³. A combination of the n⁺⁺ layer 84a and the p⁺⁺ layer 84b (hereinafter, denoted by the n⁺⁺ layer 84a/p⁺⁺ layer 84b) is, for example, n⁺⁺ GaInP/p⁺⁺ GaAs, n⁺⁺ GaInP/p⁺⁺ AlGaAs, n⁺⁺ GaAs/p⁺⁺ GaAs, n⁺⁺ AlGaAs/p⁺⁺ AlGaAs, n⁺⁺ InGaAs/p⁺⁺ InGaAs, n⁺⁺ GaInAsP/p⁺⁺ GaInAsP, or n⁺⁺ GaAsSb/p⁺⁺ GaAsSb. The combination may be changed.

The p-anode layer 85 is made of, for example, p-type Al_{0.9}GaAs with an impurity concentration of 1×10¹⁸/cm³. The Al composition may be changed within a range from 0 to 1.

The voltage reduction layer 86 has been described above.

The n-gate layer 87 is made of, for example, n-type Al_{0.9}GaAs with an impurity concentration of 1×10¹⁷/cm³. The Al composition may be changed within a range from 0 to 1.

The p-gate layer 88 is made of, for example, p-type Al_{0.9}GaAs with an impurity concentration of 1×10¹⁷/cm³. The Al composition may be changed within a range from 0 to 1.

The n-cathode layer 89 is made of, for example, n-type Al_{0.9}GaAs with an impurity concentration of 1×10¹⁸/cm³. The Al composition may be changed within a range from 0 to 1.

The tunnel junction layer 90 may be similar to the tunnel junction layer 84.

The p-anode layer 91, the voltage reduction layer 92, the n-gate layer 93, the p-gate layer 94, and the n-cathode layer 95 may be similar to the p-anode layer 85, the voltage reduction layer 86, the n-gate layer 87, the p-gate layer 88, and the n-cathode layer 89, respectively.

The above semiconductor layers are laminated by, for example, metal organic chemical vapor deposition (MOCVD), molecular beam epitaxy (MBE), or the like to form a semiconductor layer multilayer body.

In place of the AlGaAs materials mentioned above, GaInP or the like may be used. Furthermore, a GaN substrate or an InP substrate may be used. Furthermore, the laser diode LD including the p-anode layer 81, the light-emitting layer 82, and the n-cathode layer 83, the driving thyristor B including the p-anode layer 85, the voltage reduction layer 86, the n-gate layer 87, the p-gate layer 88, and the n-cathode layer 89, and the driving thyristor U including the p-anode layer 91, the voltage reduction layer 92, the n-gate layer 93, the p-gate layer 94, and the n-cathode layer 95 may be made of materials with different lattice constants. Metamorphic growth or causing the laser diode LD and the driving thyristors B and U to grow separately and then attaching them together may be implemented. At this time, the lattice constants of the tunnel junction layers 84 and 90 need to substantially match the lattice constant of one of layers in contact.

For example, on a GaN substrate, the laser diode LD including the p-anode layer 81, the light-emitting layer 82, and the n-cathode layer 83 are caused to grow using a material whose lattice constant is substantially the same as that of the GaN substrate, and after that, a layer (metamorphic layer) for causing the lattice constant to approach that of InN is formed by metamorphic growth on the laser diode LD. Then, the driving thyristor B including the tunnel junction layer 84, the p-anode layer 85, the voltage reduction layer 86, the n-gate layer 87, the p-gate layer 88, and the n-cathode layer 89 and the driving thyristor U including the tunnel junction layer 90, the p-anode layer 91, the voltage reduction layer 92, the n-gate layer 93, the p-gate layer 94, and the n-cathode layer 95 are caused to grow on the metamorphic layer using the material that has approached the lattice constant of InN (material whose energy band gap is smaller than that of GaN). Accordingly, for example, the quality and performance of tunnel junction are improved, and the driving voltage (holding voltage) in a state in which a thyristor is ON is reduced.

The light-emitting unit 100 may be produced by a well-known technique such as photolithography, etching, or the like. Therefore, explanation for a method for producing the light-emitting unit 100 will be omitted.

### (Operation of Light-Emitting Apparatus)

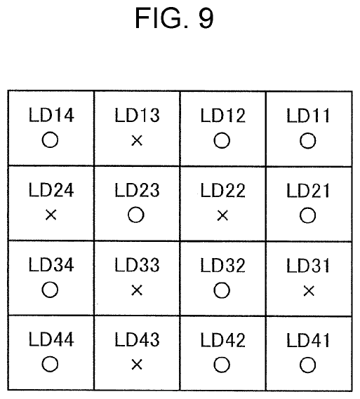

FIG. 9 is a diagram illustrating an example of the light-emitting apparatus 10 controlling ON/OFF of laser diodes LD. In this example, a case where the laser diodes LD are arranged in a 4 by 4 array, as explained with reference to FIGS. 1, 2, and so on, will be explained. In FIG. 9, laser diodes LD that are turned ON (emit light) are represented by circle marks, and laser diodes LD that are turned OFF (are not lit) are represented by cross marks. Laser diodes LD that are turned ON are denoted by ON-target laser diodes LD. In this example, laser diodes LD11, LD12, LD14, LD21, LD23, LD32, LD34, LD41, LD42, and LD44 are turned ON (emit light), and the laser diodes LD13, LD22, LD24, LD31, LD33, and LD43 are turned OFF (are not lit).

That is, when the light-emitting apparatus 10 is viewed, a state in which the “circle” portions in FIG. 9 are turned ON (emit light) is viewed. The state viewed in FIG. 9 corresponds to a state in which FIG. 1 is viewed directly. FIG. 2 corresponds to a state in which rotation by 90 degrees is performed.

### (Timing Chart)

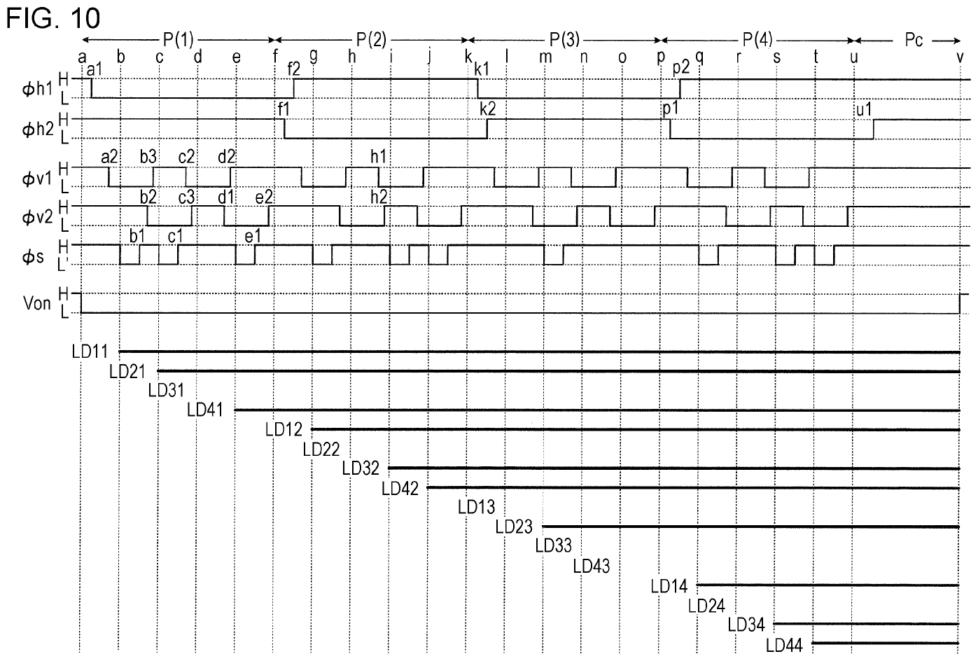

FIG. 10 is a timing chart for driving the light-emitting apparatus 10. The light-emitting apparatus 10 includes the laser diodes LD in a 4 by 4 arrangement and is controlled between an ON state and an OFF state illustrated in FIG. 9. In FIG. 10, time passes in an alphabetical order (a, b, c, and so on). A timing at which a change in the potential occurs will be explained using a sign in an appropriate manner.

In the timing chart illustrated in FIG. 10, setting periods P(1) to P(4) during which laser diodes LD are set to ON or OFF and an ON maintenance period Pc during which ON-target laser diodes LD that are set to ON are maintained in the ON state in a parallel manner are provided.

A period from time a to time f corresponds to the setting period P(1) for the laser diodes LD11, LD21, LD31, and LD41, a period from the time f to time k corresponds to the setting period P(2) for the laser diodes LD12, LD22, LD32, and LD42, a period from the time k to time p corresponds to the setting period P(3) for the laser diodes LD13, LD23, LD33, and LD43, and a period from the time p to time u corresponds to the setting period P(4) for the laser diodes LD14, LD24, LD34, and LD44. A period from the time u to time v corresponds to the ON maintenance period Pc during which ON-target laser diodes LD that are set to ON are maintained in the ON state in a parallel manner. That is, during the setting periods P(1) to P(4), at a point in time when turning ON of ON-target laser diodes LD is completed, the ON maintenance period Pc during which the ON-target laser diodes LD are maintained in the ON state in a parallel manner starts.

In this example, the setting period P(1) is an example of a first period, and any one of the setting periods P(2) to P(4) is an example of a second period. Furthermore, the ON maintenance period Pc is an example of a third period. In FIG. 10, the setting period P(1) is indicated to be longer than the ON maintenance period Pc. However, the ON maintenance period Pc is preferably set to be longer than the setting period P(1). Compared to the case where the setting period P(1) as an example of the first period is longer than the ON maintenance period Pc as an example of the third period, a difference in the amount of light emission that is dependent on the order of light emission among a plurality of laser diodes LD is reduced.

The flowchart of FIG. 10 will be explained below with reference to FIG. 1.

The reference potential Vsub is set to “H (0 V)”, and the h-direction power supply potential Vgk1 and the v-direction power supply potential Vgk2 are set to “L (−3.3 V)”.

At the time a, power is supplied to the controller 110 illustrated in FIG. 1. Then, the reference potential Vsub is set to “H (0 V)”, and the h-direction power supply potential Vgk1 and the v-direction power supply potential Vgk2 are set to “L −3.3 V)”.

Next, the wavelengths of signals (the transfer signals φh1, φh2, φv1, and φv2, the setting signal φs, and the ON signal Von) will be explained.

First, the transfer signals φh1 and φh2 will be explained. The transfer signals φh1 and φh2 are signals having potentials of “H (0 V)” and “L (−3.3 V)”.

The potential of the transfer signal φh1 is at “H 0 V)” at the time a, and is shifted to “L (−3.3 V)” at time a1, which is between the time a and the time b. Then, at time f2, which is between the time f and the time g, the potential of the transfer signal φh1 is returned to “H (0 V)”. Furthermore, at a k1, which is between the time k and the time l, the potential of the transfer signal φh1 is returned again to “L (−3.3 V)”. The transfer signal φh1 is a signal that repeats the waveform for the setting periods P(1) and P(2), which are from the time a to the time k, during a period from the time k to the time u.

In contrast, the potential of the transfer signal φh2 is at “H (0 V)” at the time a, and is shifted to “L (−3.3 V)” at time f1, which is between the time f and the time g. The time f1 is earlier than the time f2 mentioned above. Then, at time k2, which is between the time k and the time l, the potential of the transfer signal φh2 is returned to “H (0 V)”. The time k2 is later than the time k1 mentioned above. Furthermore, at time p1, which is between the time p and the time q, the potential of the transfer signal φh2 is shifted to “L (−3.3 V)”, and at time u1, which is between the time u and the time v, the potential of the transfer signal φh2 is shifted to “H (0 V)”. The transfer signal φh2 is a signal that basically repeats the waveform for the setting periods P(3) and P(4), which are from the time k to the time u. However, for the transfer signal φh2, the waveform for the period from the time a to the time k, which is a period for starting an operation, is different from the waveform for the period from the time k to the time u.

As described above, during the setting periods P(1) to P(4) except for a period from the time a to the time a1, the transfer signals φh1 and φh2 are signals that repeat “H (0 V)” and “L (−3.3 V)” such that periods during which the potentials of the transfer signal φh1 and the transfer signal φh2 are at “L (−3.3 V)” overlap, as in the period from the time f1 to the time f2.

Next, the transfer signals φv1 and φv2 will be explained. The transfer signals φv1 and φv2 are signals that have potentials of “H (0 V)” and “L (−3.3 V)”. Here, the transfer signals φv1 and φv2 during the setting period P(1) will be explained.

The potential of the transfer signal φv1 is at “H (0 V)” at the time a, and is shifted to “L (−3.3 V)” at time a2, which is between the time a and the time b. The time a2 is later than the time a1 mentioned above. Then, at time b3 between the time b and the time c, the potential of the transfer signal φv1 is shifted to “H (0 V)”. At time c2, which is between the time c and the time d, the potential of the transfer signal φv1 is shifted to “L (−3.3 V)”. Then, the potential of the transfer signal φv1 is shifted to “H (0 V)” at time d2, which is between the time d and the time e. At the time f, the potential of the transfer signal φv1 is maintained at “H (0 V)”.

The transfer signal φv1 is a signal that repeats the waveform for the setting period P(1), which is from the time a to the time f, during the setting periods P(2) to P(4).

The potential of the transfer signal φv2 is at “H (0 V)” at the time a, and is shifted to “L (−3.3 V)” at time b2, which is between the time b and the time c. The time b2 is earlier than the time b3 mentioned above. Then, at time c3, which is between the time c and the time d, the potential of the transfer signal φv2 is shifted to “H (0 V)”. The time c3 is later then the time c2. At time d1, which is between the time d and the time e, the potential of the transfer signal φv2 is shifted to “L (−3.3 V)”. The time d1 is earlier than the time d2 mentioned above. At time e2, which is between the time e and the time f, the potential of the transfer signal φv2 is shifted to “H (0 V)”. At the time f, the potential of the transfer signal φv2 is maintained at “H (0 V)”.

The transfer signal φv2 is a signal that repeats the waveform for the setting period P(1), which is from the time a to the time f, during the setting periods P(2) to P(4).

As described above, the transfer signals φv1 and φv2 are signals that repeat “H (0 V)” and “L (−3.3 V)” such that during the period from the time b to the time f, periods during which the potentials of the transfer signal φv1 and the transfer signal φv2 are at “L (−3.3 V)” overlap, as in the period from the time b2 to the time b3. Since the period from the time a to the time a2 is a period for starting an operation, the potentials of both the transfer signal φv1 and the transfer signal φv2 at the time a are “H (0 V)”.

Next, the setting signal φs will be explained. The setting signal φs is a signal that has potentials of “H (0 V)” and “L′ (−3 V)”. The setting signal φs during the setting period P(1) will be explained below.

The potential of the setting signal φs is at “H (0 V)” at the time a, and is shifted to “L′ (−3 V)” at the time b. Then, at time b1, which is between the time b and the time c, the potential of the setting signal φs is shifted to “H (0 V)”. The time b1 is earlier than the time b2 mentioned above.

As illustrated in FIG. 9, the laser diode LD 11 is ON. Therefore, at the time b, the potential of the setting signal φs is shifted from “H (0 V)” to “L′ (−3 V)”. That is, to turn ON a laser diode LD, the potential of the setting signal φs is shifted from “H (0 V)” to “L′ (−3 V)”. Then, at the time b1, which is between the time b and the time c, the potential of the setting signal φs is shifted to “H (0 V)”. The time b1 is earlier than the time b2 mentioned above.

Furthermore, as illustrated in FIG. 9, since the laser diode LD21 is ON, the potential of the setting signal φs is shifted from “H (0 V)” to “L′ (−3 V)” at the time c. Then, at time c1, which is between the time c and the time d, the potential of the setting signal φs is shifted to “H (0 V)”. The time c1 is earlier than the time c2 mentioned above.

Then, since the laser diode LD31 is kept OFF, the potential of the setting signal φs is maintained at “H (0 V)” during the period from the time d to the time e.

As described above, the setting signal φs is a signal for setting a laser diode LD to ON or OFF. During a predetermined period, ON-target laser diodes LD are turned ON by causing the potential of the setting signal φs to be shifted to “L′ (−3 V)”, and laser diodes LD are turned OFF by causing the potential of the setting signal φs to be maintained at “H (0 V)”.

In the setting period P(1), a period from the time b to the time c corresponds to a period during which the laser diode LD11 is set to ON or OFF, a period from the time c to the time d corresponds to a period during which the laser diode LD21 is set to ON or OFF, a period from the time d to the time e corresponds to a period during which the laser diode LD31 is set to ON or OFF, and a period from the time e to the time f corresponds to a period during which the laser diode LD41 is set to ON or OFF. A period from the time a to the time b is a period during which an operation starts.

The setting period P(2) is a period during which the laser diodes LD12, LD22, LD32, and LD42 are set to ON or OFF, the setting period P(3) is a period during which the laser diodes LD13, LD23, LD33, and LD43 are set to ON or OFF, and the setting period P(4) is a period during which the laser diodes LD14, LD24, LD34, and LD44 are set to ON or OFF.

Next, the ON signal Von will be explained. The ON signal Von is a signal that has potentials of “H (0 V)” and “L (−3.3 V)”. The ON signal Von is shifted from “H (0 V)” to “L (−3.3 V)” at the time a. Then, at the time v, the potential of the ON signal Von is shifted to “H (0 V)”.

During the setting period P(1), the laser diodes LD11, LD21, LD31, and LD41 are set to ON or OFF sequentially. During the setting period P(2), which is subsequent to the setting period P(1), the laser diodes LD12, LD22, LD32, and LD42 are set to ON or OFF sequentially. During the setting period P(3), which is subsequent to the setting period P(2), the laser diodes LD13, LD23, LD33, and LD43 are set to ON or OFF sequentially. During the setting period P(4), which is subsequent to the setting period P(3), the laser diodes LD14, LD24, LD34, and LD44 are set to ON or OFF sequentially.

Then, during the ON maintenance period Pc, laser diodes LD that have been set to ON are kept ON in a parallel manner.

Then, at the time v, at which the ON maintenance period Pc ends, the ON signal Von is shifted from “L (−3.3 V)” to “H (0 V)”. Accordingly, all the laser diodes LD that have been kept ON are turned OFF. After that, time returns to the time a.

Then, during a period in which the potential of the setting signal φs is at “L′ (−3 V)”, ON-target laser diodes LD are selected.

An operation of the light-emitting unit 100 at specific times in the timing chart illustrated in FIG. 10 will be explained below with reference to drawings in which part of the equivalent circuit illustrated in FIG. 1 is extracted. In the drawings, an ON state of thyristors (the transfer thyristors Th1 and Tv1, the setting thyristor S1, the driving thyristor U11 and B11, etc.) is denoted by “On”, and an OFF state of thyristors (the transfer thyristors Th1 and Tv1, the setting thyristor S1, the driving thyristors U11 and B11, etc.) is denoted by “Off”. Furthermore, potential is denoted by [ ].

### (1) Time a1

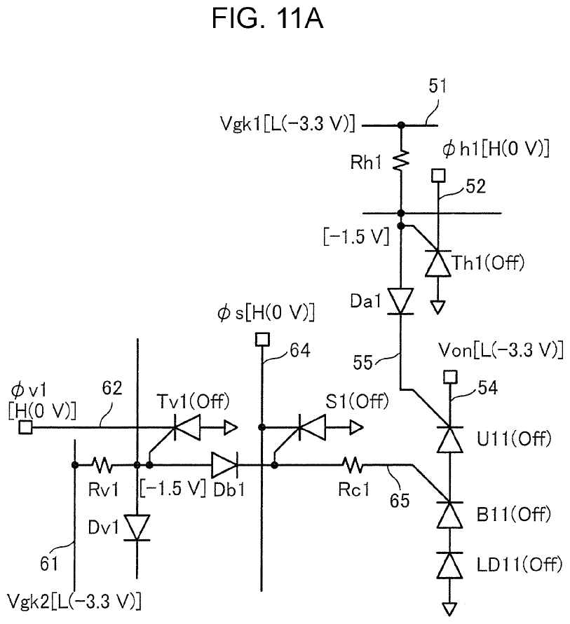

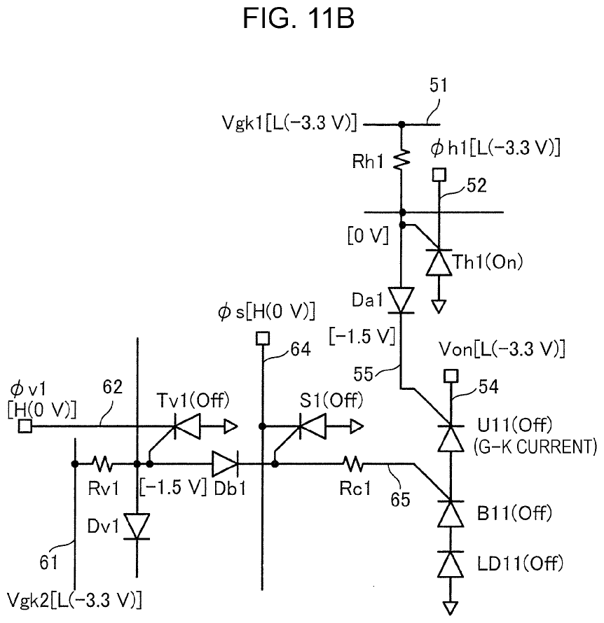

FIGS. 11A and 11B are diagrams for explaining an operation at the time a1. FIG. 11A illustrates a state immediately before the time a1, and FIG. 11B illustrates a state immediately after the time a1. In each of FIGS. 11A and 11B, an equivalent circuit of a part associated with the driving thyristor B11/the driving thyristor U11/the laser diode LD11 is illustrated. The state immediately before the time a1 represents a state in which the potential of the transfer signal φh1 is at “H (0 V)” before the potential of the transfer signal φh1 is shifted from “H (0 V)” to “L (−3.3 V)” at the time a1. In contrast, the state immediately after the time a1 represents a state in which the potential of the transfer signal φh1 is at “L (−3.3 V)”.

First, the state immediately before the time a1 in FIG. 11A will be explained.

At the time a, the controller 110 sets the h-direction power supply potential Vgk1 and the v-direction power supply potential Vgk2 to “L (−3.3 V)”. The reference potential Vsub is “H (0 V)”. Accordingly, the potentials of the power supply line 51 and the power supply line 61 become “L (−3.3 V)” (see FIG. 1).

Then, the transfer signals φh1, φh2, φv1, and φv2 and the setting signal φs are set to “H (0 V)”. The ON signal Von is shifted from “H (0 V)” to “L (−3.3 V)”. Thus, the potentials of the transfer signal lines 52, 53, 62, and 63 and the setting signal line 64 of the light-emitting unit 100 become “H (0 V)”. Then, the potential of the ON signal line 54 of the light-emitting unit 100 becomes “L (−3.3 V)”.

In the h-direction transfer part 102, the anode of the start diode Dhs is connected to the transfer signal line 53 to which the transfer signal φh2 at “H (0 V)” is supplied, and the cathode of the start diode Dhs is connected, via the resistor Rh1, to the power supply line 51 to which the h-direction power supply potential Vgk1 at “L (−3.3 V)” is supplied. Therefore, the cathode of the start diode Dhs is set to −1.5 V. Since the cathode of the start diode Dhs is connected to the gate of the transfer thyristor Th1, the potential of the gate of the transfer thyristor Th1 becomes −1.5 V, and the threshold voltage becomes −3 V. The potential of the gate of the transfer thyristor Th2 whose gate is connected to the transfer thyristor Th1 by the coupling diode Dv1 becomes −3 V, and the threshold voltage becomes −4.5 V. The transfer thyristors Th3 and Th4 are not affected by the potential of the gate of the transfer thyristor Th1 at −1.5 V, and the potentials of the gates of the transfer thyristors Th3 and Th4 become “H (−3.3 V)”, which is the potential of an h-direction power supply potential Vhk1 of the power supply line 51 connected to the resistors Rh3 and Rh4, and the threshold voltage becomes −4.8 V.

The same applies to the v-direction transfer part 103. Therefore, explanation for the v-direction transfer part 103 will be omitted.

That is, in the state immediately before the time a1, the potential of the gate of the transfer thyristor Th1 becomes −1.5 V, and the threshold voltage becomes −3 V. Similarly, the potential of the gate of the transfer thyristor Tv1 becomes −1.5 V, and the threshold voltage becomes −3 V. All the transfer thyristor Th1, the transfer thyristor Tv1, the setting thyristor S1, the driving thyristor U11, and the driving thyristor B11 are in the OFF state.

Next, the state immediately after the time a1 will be explained.

At the time a1, the transfer signal φh1 is shifted from “H (0 V)” to “L (−3.3 V)”, and the potential of the transfer signal line 52 to which the transfer signal φh1 is supplied becomes “L (−3.3 V)”. Accordingly, the transfer thyristor Th1 whose threshold voltage was −3 V is turned ON, and enters the ON state. Thus, the potential of the gate of the transfer thyristor Th1 becomes 0 V. The potential of the gate of the driving thyristor U11 becomes −1.5 V via the connection diode Da1. The cathode of the driving thyristor U11 is connected to the ON signal line 54 to which the ON signal Von at “L (−3.3 V)” is supplied. Since the gate is the p-gate layer 88 and the cathode is the n-cathode layer 89, a forward bias of 1.8 V is applied between the gate and the cathode. Since the forward potential Vd is −1.5 V, a state in which current flows between the gate and the cathode is obtained. Also in the other driving thyristors U21, U31, and U41 connected to the cathode of the connection diode Da1, the state in which current flows between the gate and cathode is obtained. In FIG. 11B, gate-cathode is denoted by G-K, and the state in which current flows is denoted by (G-K current).

In the state immediately after the time a1, when a potential of a holding voltage Vh (0.8 V) or more as an absolute value is applied between the anode and cathode of each of the driving thyristors U11, U21, U31, and U41, the ON state may be entered.

### (2) Time a2 and Time b

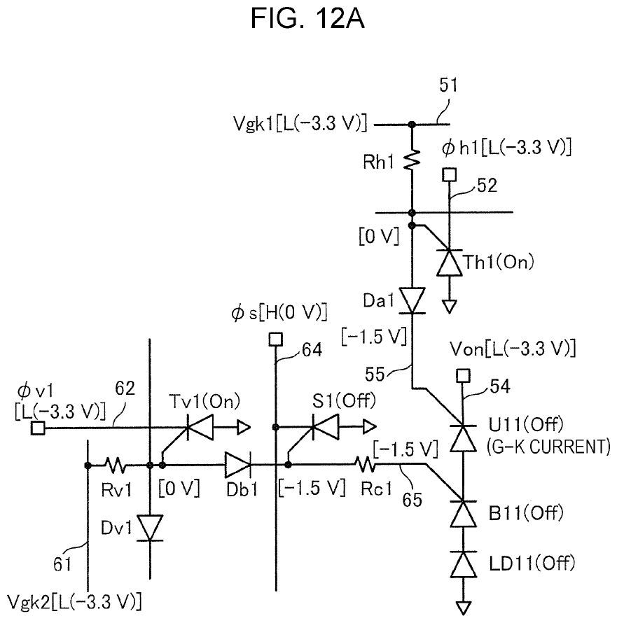

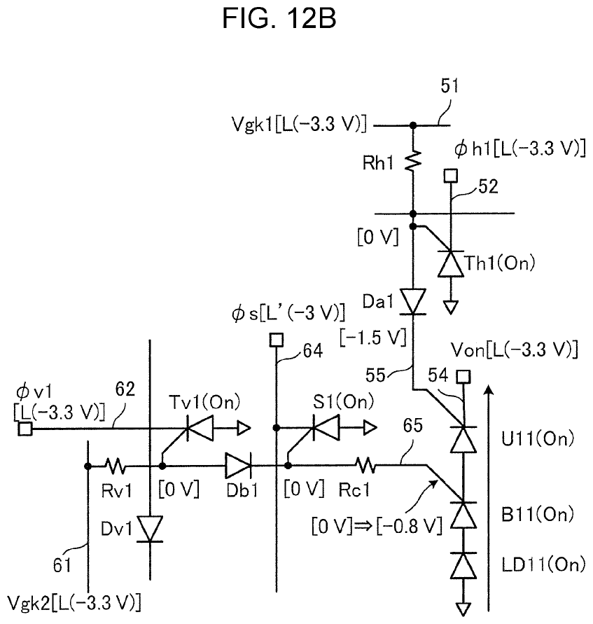

FIGS. 12A and 12B are diagrams for explaining an operation at the time a2 and the time b. FIG. 12A illustrates a state immediately after the time a2, and FIG. 12B illustrates a state immediately after the time b. The state immediately after the time a2 represents a state in which the potential of the transfer signal φv1 is at “L (−3.3 V)” after the potential of the transfer signal φv1 is shifted from “H (0 V)” to “L (−3.3 V)” at the time a2. Furthermore, the state immediately after the time b1 represents a state in which the potential of the setting signal φs is at “L′ (−3 V)” after the potential of the setting signal φs is shifted from “H (0 V)” to “L′ (−3 V)” at the time b1.

First, the state immediately after the time a2 illustrated in FIG. 12A will be explained.

At the time a2, the potential of the transfer signal φv1 is shifted from “H (0 V)” to “L (−3.3 V)”, and the potential of the transfer signal line 62 to which the transfer signal φv1 is supplied is shifted to “L (−3.3 V)”. Thus, the transfer thyristor Tv1 whose threshold voltage was −3 V is turned ON and enters the ON state. Accordingly, the potential of the gate of the transfer thyristor Tv1 becomes 0 V. Thus, the potential of the gate of the setting thyristor S1 becomes −1.5 V via the connection diode Db1, and the threshold voltage becomes −3 V. Furthermore, the potential of the gate of the driving thyristor B11 becomes −1.5 V via the connection resistor Rc1. Accordingly, the potential of the cathode of the driving thyristor B11 (anode of the driving thyristor U11) becomes −3 V. Therefore, the potential applied between the anode and cathode of the driving thyristor U11 is 0.3 V as an absolute value, which is smaller than the potential 0.8 V for turning ON the driving thyristor U11. The driving thyristor U11 is in the OFF state.

Next, the state immediately after the time b illustrated in FIG. 12B will be explained.

At the time b, the setting signal φs is shifted from “H (0 V)” to “L′ (−3 V)”, and the setting thyristor S1 whose threshold voltage was −3 V is turned ON and enters the ON state. Thus, the potential of the gate of the setting thyristor S1 becomes 0 V. The potential of the gate of the driving thyristor B11 becomes 0 V by the connection resistor Rc1. Accordingly, the potential of the cathode of the driving thyristor B11 (anode of the driving thyristor U11) becomes −1.5 V. Therefore, the potential applied between the cathode and anode of the driving thyristor U11 becomes −1.8 V, and the driving thyristor U11 is turned ON and enters the ON state.

When the driving thyristor U11 enters the ON state and current starts to flow to the driving thyristor U11, current also flows between the gate and cathode of the driving thyristor B11. Thus, the potential of the gate of the driving thyristor B11 approaches −0.8 V due to a potential drop of the connection resistor Rc1. Accordingly, the potential of the cathode of the driving thyristor B11 (anode of the driving thyristor U11) approaches −2.3 V. At this time, the potential of the anode of the driving thyristor B11, which is connected to the cathode of the laser diode LD11, becomes −1.5 V. That is, 0.8 V is applied between the anode and cathode of the driving thyristor B11. Accordingly, the driving thyristor B11 is turned ON and enters the ON state. Thus, as indicated by an arrow in the drawing, current flows to the laser diode LD11, the driving thyristor B11, and the driving thyristor U11, and the laser diode LD11 is turned ON.

Depending on the structure of the light-emitting unit 100, immediately after the driving thyristor U11 is turned ON, the driving thyristor B11 may be turned ON before the potential of the gate of the driving thyristor B11 becomes −0.8 V.

A potential supplied to the gate of the driving thyristor U to turn ON the driving thyristor U (for example, −1.5 V) and a potential supplied to the gate of the driving thyristor B to turn ON the driving thyristor B (for example, −0.8 V) are examples of control signals input to the gates of the driving thyristors B and U.

### (3) Time b1 and Time b2

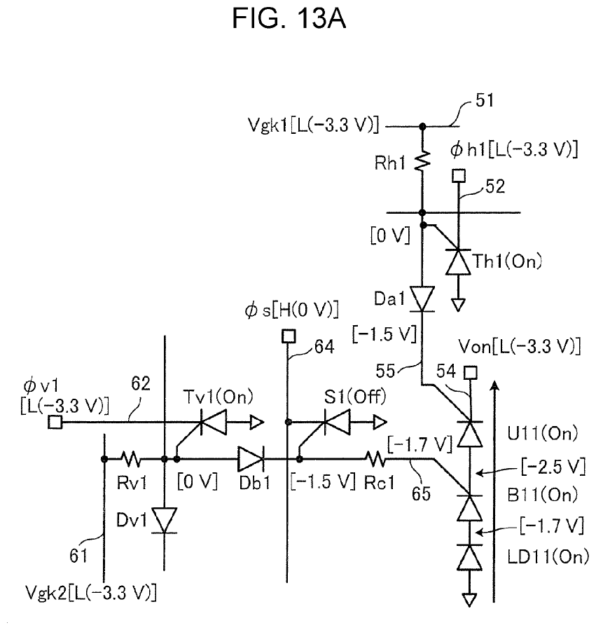

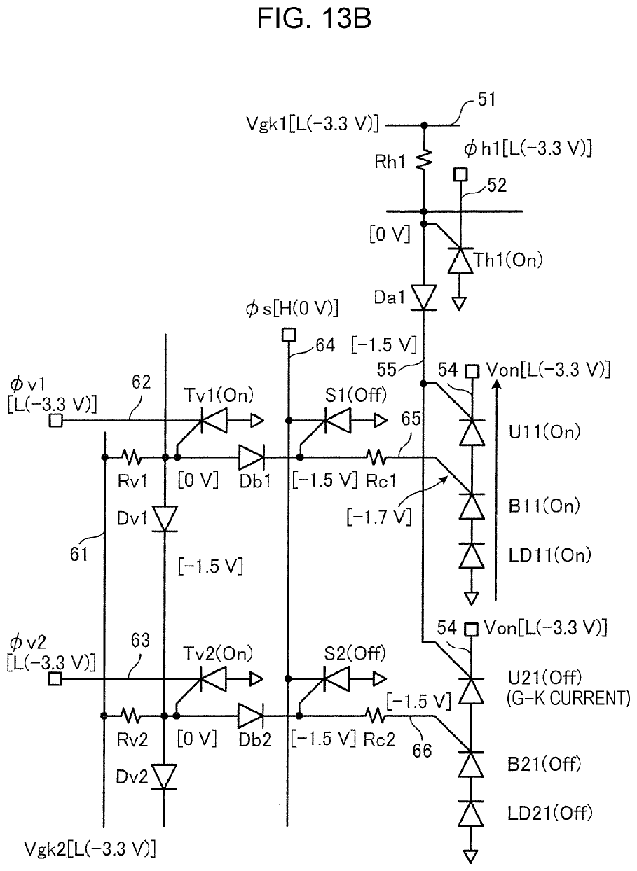

FIGS. 13A and 13B are diagrams for explaining an operation at the time b1 and the time b2. FIG. 13A illustrates the state immediately after the time b1, and FIG. 13B illustrates the state immediately after the time b2. The state immediately after the time b1 represents a state in which the potential of the setting signal φs is at “H (0 V)” after the potential of the setting signal φs is shifted from “L′ (−3 V)” to “H (0 V)” at the time b1. The state immediately after the time b2 represents a state in which the potential of the transfer signal φv2 is at “L (−3.3 V)” after the potential of the transfer signal φv2 is shifted from “H (0 V)” to “L (−3.3 V)” at the time b2.

First, the state immediately after the time b1 illustrated in FIG. 13A will be explained.

At the time b1, the potential of the setting signal φs is shifted from “L′ (−3 V)” to “H (0 V)”. Thus, the potential of the setting signal line 64 to which the setting signal φs is supplied becomes “H (0 V)”. Since the cathode of the setting thyristor S1 is connected to the setting signal line 64, potentials of both the anode and the cathode of the setting thyristor S1 become “H (0 V)”, and the setting thyristor S1 is turned OFF and enters the OFF state.

At this time, the potential of the ON signal Von is kept at “L (−3.3 V)”, and the driving thyristors B11 and U11 thus maintain the ON state. Therefore, current flows to the driving thyristor U11, the driving thyristor B11, and the laser diode LD11, and the laser diode LD11 are kept ON.

For example, in the above state, the potential of the cathode of the driving thyristor U11 is at −3.3 V (the ON signal Von), and the potential of the anode of the laser diode LD11 is at 0 V (the reference potential Vsub). Potentials of the gate and anode of the driving thyristor U11 and the cathode of the driving thyristor B11 are within the range from −1.5 V to −2.5 V. In FIG. 13A, the potentials of the gate and anode of the driving thyristor U11 and the cathode of the driving thyristor B11 are set to −2.5 V. Furthermore, potentials of the gate and anode of the driving thyristor B11 and the cathode of the laser diode LD11 are set to −1.7 V. There is a potential drop of 0.2 V in the laser diode LD11.

Next, the state immediately after the time b2 illustrated in FIG. 13B will be explained. In FIG. 13B, the driving thyristor Tv2, the driving thyristor U21/driving thyristor B21/laser diode LD21, and the like are additionally described.

At the time b2, the potential of the transfer signal φv2 is shifted from “H (0 V)” to “L (−3.3 V)”, and the potential of the transfer signal line 63 to which the transfer signal φv2 is supplied becomes “L (−3.3 V)”. Thus, the transfer thyristor Tv2 whose threshold voltage was −3 V is turned ON and enters the ON state. Thus, the potential of the gate of the transfer thyristor Tv2 becomes 0 V, and the potential of the gate of the driving thyristor B21 becomes −1.5 V. At this time, current flows between the gate and cathode of the driving thyristor U21. However, since the potential of the anode of the driving thyristor U21 (cathode of the driving thyristor B21) is at −3 V, the driving thyristor U21 is not turned ON.

At this time, since the potential of the ON signal Von is kept at “L (−3.3 V)”, the driving thyristors B11 and U11 maintain the ON state. Therefore, current flows to the laser diode LD11, the driving thyristor B11, and the driving thyristor U11, and the laser diode LD11 is kept ON.

At the time b3, the transfer signal φv1 is shifted from the “L (−3.3 V)” to “H (0 V)”. Thus, the potential of the transfer signal line 62 to which the transfer signal φv1 is supplied becomes “H (0 V)”. Accordingly, potentials of both the anode and cathode of the transfer thyristor Tv1 become “H (0 V)”, which is the same as the reference potential Vsub, and the transfer thyristor Tv1 is thus turned OFF and enters the OFF state. The potential of the gate of the transfer thyristor Tv1 becomes the v-direction power supply potential Vgk2, which is “L (−3.3 V)”. That is, the threshold voltage of the transfer thyristor Tv1 becomes −4.8 V. In contrast, the gate of the setting thyristor S1 is connected to the gate of the driving thyristor B11 with the connection resistor Rc1 interposed therebetween. As described above, the potential of the gate of the driving thyristor B11 is at −1.7 V. Therefore, the threshold voltage of the setting thyristor S1 becomes −3.2 V.

Also at this time, the ON signal Von is maintained at “L (−3.3 V)”, and the driving thyristors B11 and U11 thus maintain the ON state. Therefore, current flows to the driving thyristor U11, the driving thyristor B11, and the laser diode LD11, and the laser diode LD11 is kept ON.

At the time b3, the transfer thyristor Tv2 is in the ON state. Therefore, the potential of the gate of the transfer thyristor Tv2 is at 0 V. Since the gate of the setting thyristor S2 is connected to the gate of the transfer thyristor Tv2 with the connection diode Dv2 interposed therebetween, the threshold voltage of the setting thyristor S2 is set to −3 V.

At the time c, the setting signal φs is shifted from “H (0 V)” to “L′ (−3 V)”, and the potential of the setting signal line 64 to which the setting signal φs is supplied becomes “L′ (−3 V)”. Thus, the setting thyristor S2 whose threshold voltage was −3 V is turned ON and enters the ON state. Accordingly, as described above, the driving thyristors U21 and B21 are turned ON and enter the ON state, current flows to the laser diode LD21, the driving thyristor B21, and the driving thyristor U21, and the laser diode LD21 is turned ON.

The setting thyristor S1, which has a threshold voltage of −3.2 V, is not turned ON.

In contrast, as at the time d, if the setting signal φs is not shifted from “H (0 V)” to “L′ (−3 V)” and is maintained at “H (0 V)”, the potential of the setting signal line 64 to which the setting signal φs is supplied is maintained at “H (0 V)”. Therefore, the setting thyristor S is not turned ON. Thus, as in the state immediately after the time a2 illustrated in FIG. 12A, the potential of the gate of the driving thyristor B is maintained at −1.5 V. Therefore, the potential of the cathode of the driving thyristor B (anode of the driving thyristor U) is maintained at −3 V, and the driving thyristor U maintains the OFF state. That is, the laser diode LD is not turned ON.

When the potential of the gate of the driving thyristor B becomes −1.5 V and slight current flows between the gate and cathode of the driving thyristor B, the driving thyristor B may be turned ON. In order to avoid the driving thyristor B from being turned ON, a resistor or a diode may be added between the gate of the transfer thyristor Tv and the gate of the driving thyristor B so that the potential of the gate of the driving thyristor B may be set to a further negative side.

As described above, during the period from the time b to the time f in which the transfer thyristor Th1 is in the ON state, the laser diodes LD11, LD21, LD31, and LD41 are set to ON or OFF sequentially. That is, the ON-target laser diodes LD are controlled to be turned ON sequentially.

### (4) Time f1

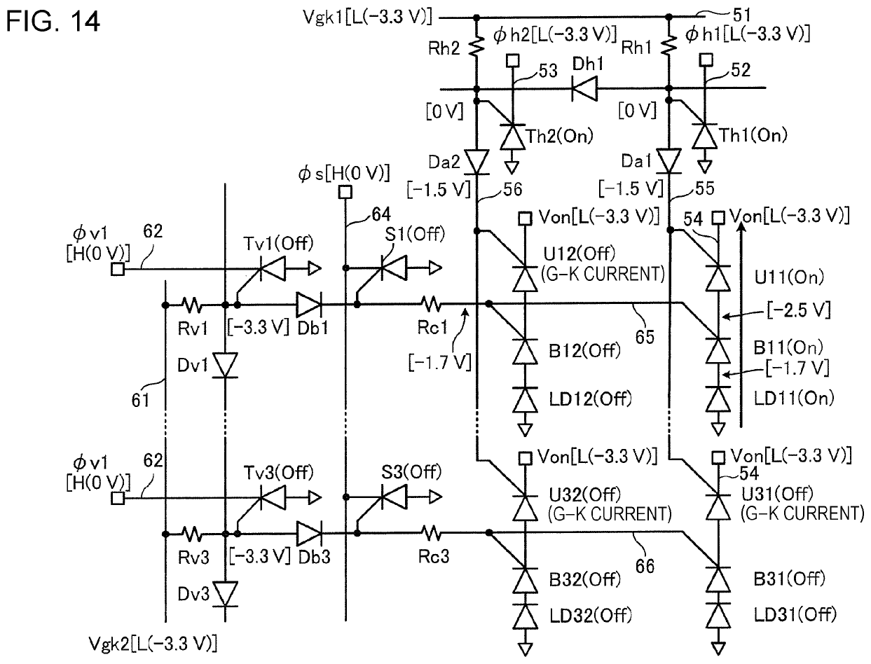

FIG. 14 is a diagram for explaining an operation at the time f1. That is, FIG. 14 illustrates a state immediately after the time f1. The state immediately after the time f1 represents a state in which the potential of the transfer signal φh2 is at “L (−3.3 V)” immediately after the potential of the transfer signal φh2 is shifted from the “H (0 V)” to “L (−3.3 V)”. As illustrated in FIG. 10, in this state, the laser diodes LD11, LD21, and LD41 are set to ON and the laser diode LD31 is set to OFF. In FIG. 14, in addition to part of the laser diode LD11 that is ON and part of the laser diode LD13 that is OFF, part associated with the laser diodes LD12 and LD32 that are set to ON or OFF are also illustrated.

At the time f (the potential of the transfer signal φh1 is at “L (−3.3 V)” and the potential of the transfer signal φh2 is at “H (0 V)”), which is immediately before the time f1, the transfer thyristor Th1 is in the ON state, as described above. Furthermore, as illustrated in FIG. 10, the potentials of the transfer signals φv1 and φv2 are at “H (0 V)”, and the transfer thyristors Tv1 and Tv3 are in the OFF state. However, the potential of the ON signal Von is at “L (−3.3 V)”, the driving thyristor U11 and the driving thyristor B11 are in the ON state, current flows to the driving thyristor U11, the driving thyristor B11, and the laser diode LD11, and the laser diode LD11 maintains the ON state. The same applies to the laser diodes LD21 and LD41.

At the time f1, the potential of the transfer signal φh2 is shifted from “H (0 V)” to “L (−3.3 V)”, and the potential of the transfer signal line 53 to which the transfer signal φh2 is supplied becomes “L (−3.3 V)”. Accordingly, the transfer thyristor Tv2 whose threshold voltage was −3 V is turned ON. Thus, the potential of the gate of the transfer thyristor Tv1 becomes 0 V, the potential of the gate of the driving thyristor U12 becomes −1.5 V, and current flows between the gate and the cathode. The same applies to the other driving thyristors U22, U32, and U42.

At this time, since the driving thyristors U11 and B11 are in the ON state, the potential of the gate of the driving thyristor B12 is at −1.7 V. Therefore, the potential of the cathode of the driving thyristor B11 (anode of the driving thyristor U12) becomes −3.2 V, which is obtained by subtracting the forward potential Vd (1.5 V). Therefore, a state in which an absolute value of 0.1 V, which is smaller than 0.8 V for turning ON the driving thyristor U12, is applied between the anode and cathode of the driving thyristor U12 is obtained. Thus, the driving thyristor U12 is not turned ON.

Even if the gate of the driving thyristor B12 is connected to the gate of the driving thyristor B11 in the ON state or the transfer thyristor Th2 is shifted to the ON state, the driving thyristor U12, which is connected to the driving thyristor B12, is not turned ON.

In contrast, the gate of the driving thyristor B32 is connected to the gate of the driving thyristor B31 for driving the laser diode LD31 in the OFF state, and the potential of the gate of the transfer thyristor Tv3 is maintained close to −3.3 V. That is, the potential of the gate of the driving thyristor B32 is −1.7 V or less. Therefore, the driving thyristor U32 is not turned ON.

As described above, since the potentials of the gates of the driving thyristors B12 and B32 are −1.7 or less, even if the transfer thyristor Th2 is turned ON, the driving thyristors B12 and B32 and the driving thyristors U12 and U32 maintain the OFF state. Therefore, the laser diodes LD12 and LD32 are not turned ON.

The laser diodes LD12 and LD32 have been explained above as examples. The laser diodes LD22 and LD42 are similar to the laser diode LD12.

Next, although not illustrated in FIG. 14, at the time f2, the potential of the transfer signal φh1 is shifted from “L (−3.3 V)” to “H (0 V)”, and the potential of the transfer signal line 52 to which the transfer signal φh1 is supplied becomes “H (0 V)”. Accordingly, the transfer thyristor Th1 is turned OFF and enters the OFF state. Thus, the potential of the gate of the transfer thyristor Th1 becomes “L (−3.3 V)” via the resistor Rh1. Therefore, the potential of the gate of the driving thyristor U11 is not −1.5 V anymore. However, the laser diode LD11 and the driving thyristor B11 are in the ON state, and the laser diode LD11 maintains the ON state. As described above, the potential of the anode of the driving thyristor U11 is −2.5 V. Therefore, the potential of the gate of the driving thyristor U11 in the ON state becomes −2.5 V, which is equal to the potential of the anode of the driving thyristor U11.

### (5) Time i

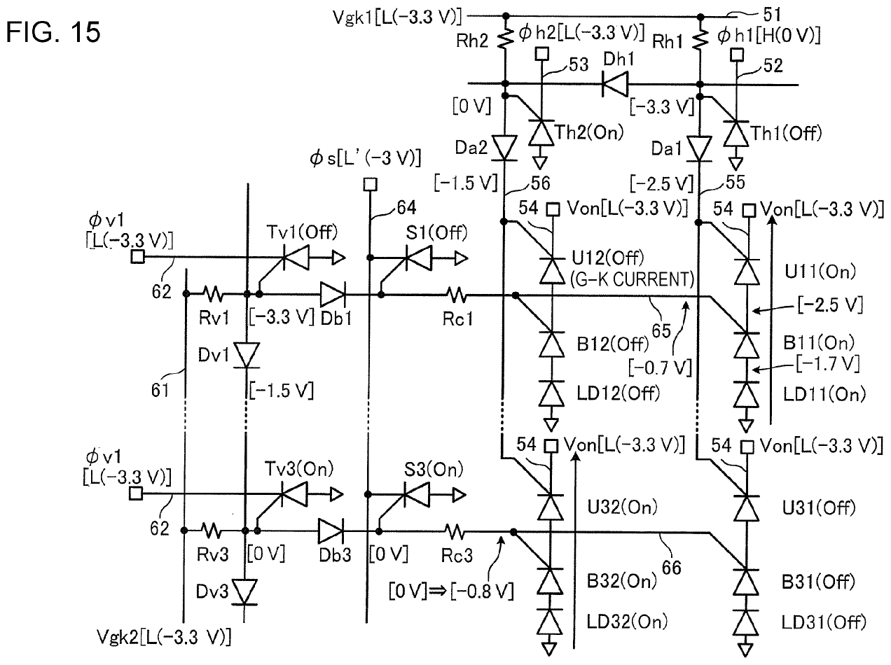

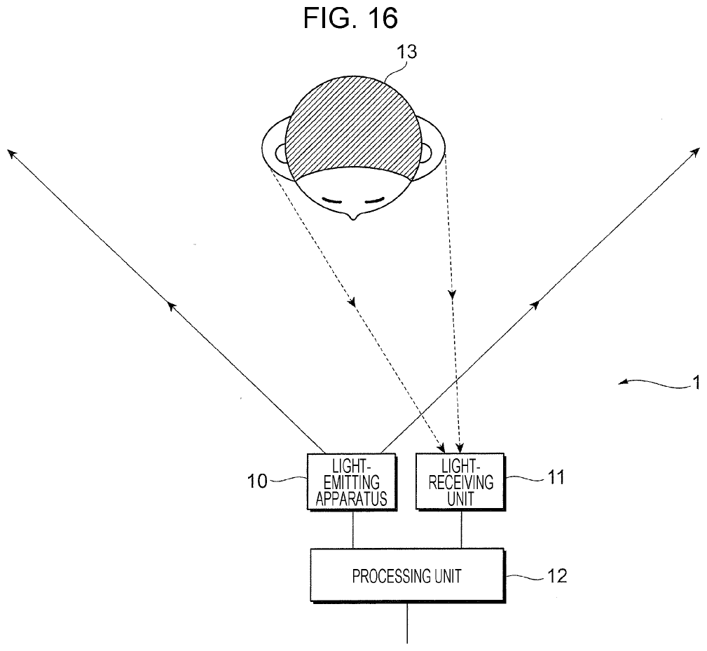

FIG. 15 is a diagram for explaining an operation at the time i. That is, FIG. 15 illustrates a state immediately after the time i. The state immediately after the time i represents a state in which the potential of the transfer signal φv2 is at “H (0 V)” and the potential of the setting signal φs is at “L′ (−3 V)” immediately after the potential of the transfer signal φv2 is shifted from “L (−3.3 V)” to “H (0 V)” and the potential of the setting signal φs is shifted from “H (0 V)” to “L′ (−3 V)”.

At the time f2, which is before the time i, the potential of the transfer signal φh1 is shifted from “L (−3.3 V)” to “H (0 V)”, and the potential of the transfer signal line 52 to which the transfer signal φh1 is supplied becomes “H (0 V)”. Accordingly, the transfer thyristor Th1 enters the OFF state. At the time h1, which is between the time h and the time i, the potential of the transfer signal φv1 is shifted from “H (0 V)” to “L (−3.3 V)”, and the potential of the transfer signal line 62 to which the transfer signal φv1 is supplied becomes “L (−3.3 V)”. Accordingly, the transfer thyristor Tv3 is turned ON. The transfer thyristors Tv1 and Tv4 are in the OFF state, and the transfer thyristor Tv2 is in the ON state.

Therefore, at the time h1, the potentials of the gates of the setting thyristors S2 and S3 become −1.5 V, and the threshold voltage becomes −3 V. The threshold voltage of the other setting thyristors S1 and S4 is lower than −3 V.

At time h2, which is between the time h and the time i, first, the potential of the transfer signal φv2 is shifted from “L (−3.3 V)” to “H (0 V)”, and the potential of the transfer signal line 63 to which the transfer signal φv2 is supplied becomes “H (0 V)”. Accordingly, the transfer thyristor Tv2 is turned OFF and enters the OFF state. Thus, the threshold voltage of the setting thyristor S2 become −3 V. The time h2 is later than the time h1 mentioned above.

Then, at the time i, the potential of the setting signal φs is shifted from “H (0 V)” to “L′ (−3 V)”, and the potential of the setting signal line 64 to which the setting signal φs is supplied becomes “L′ (−3 V)”. Accordingly, the setting thyristor S3 whose threshold voltage was −3 V is turned ON. Thus, as described for the time b, the driving thyristors U32 and B32 are turned ON, and the laser diode LD32 is turned ON.

Since the potential of the gate of the driving thyristor U31 for driving the laser diode LD 31 in the OFF state is −2.5 V, the potential difference between the gate and cathode of the driving thyristor U31 is 0.8 V, which is smaller than the forward potential Vd (1.5 V). Therefore, no current flows between the gate and cathode of the driving thyristor U31. Thus, the driving thyristors U31 and B31 are not turned ON.

That is, when the setting thyristor S that is connected to the transfer thyristor Tv in the ON state is turned ON in accordance with shifting of the potential of the setting signal φs from “H (0 V)” to “L′ (−3 V)”, the driving thyristor B and the driving thyristor U that are connected to the transfer thyristor Th in the ON state and the transfer thyristor Tv in the ON state are turned ON, and the laser diode LD is thus turned ON. The driving thyristor B and the driving thyristor U that are connected to the transfer thyristor Th and the transfer thyristor Tv at least one of which is in the OFF state, are not turned ON.

The driving thyristor B and the driving thyristor U that have been turned ON and entered the ON state maintain the ON state as long as the ON signal Von is at “L (−3.3 V)”. That is, the laser diodes LD that are driven by the driving thyristor B and the driving thyristor U that have entered the ON state maintain the ON state in a parallel manner.

Therefore, at the time v in FIG. 10, the ON signal Von is shifted from “L (−3.3 V)” to “H (0 V)”, and the laser diodes LD that are in the ON state in a parallel manner are turned OFF and enter the OFF state.

Operations of the light-emitting unit 100 at principal times in the timing chart illustrated in FIG. 10 have been described above. Operations at other times may be easily understood from the above explanation. Therefore, explanation for operation at other times will be omitted.

Supplementary explanation for operations of the h-direction transfer part 102 and the v-direction transfer part 103 will be provided below with reference to FIGS. 1 to 10.

At the time a, in the h-direction transfer part 102, the threshold voltage of the transfer thyristor Th1 is at −3 V due to the start diode Dhs. Therefore, at the time a1, the potential of the transfer signal φh1 is shifted from “H (0 V)” to “L (−3.3 V)”, and the transfer thyristor Th1 is turned ON and enters the ON state. Thus, the potential of the gate of the transfer thyristor Th1 becomes 0 V. Therefore, the gate of the transfer thyristor Th2 that is connected via the coupling diode Dh1 becomes −1.5 V, and the threshold voltage becomes −3 V. At the time f1, the potential of the transfer signal φh2 is shifted from “H (0 V)” to “L (−3.3 V)”, and the transfer thyristor Th2 whose threshold voltage was −3 V is turned ON and enters the ON state. Thus, as at the time a1, the threshold voltage of the transfer thyristor Th3 becomes −3 V.

Next, at the time f2, the transfer signal φh1 is shifted from “L (−3.3 V)” to “H (0 V)”, and the transfer thyristor Th1 is turned OFF and enters the OFF state. Thus, the potential of the gate of the transfer thyristor Th1 becomes “L (−3.3 V)”, which is equal to the h-direction power supply potential Vgk1, and the threshold voltage of the transfer thyristor Th1 becomes −4.8 V. Then, the coupling diode Dh1 becomes reverse-biased, and therefore, there is no influence of the potential of the gate of the transfer thyristor Th1 being 0 V. That is, the transfer signals φh1 and φh2 are set to be signals that exhibit “H (0 V)” and “L (−3.3 V)” alternately such that periods during which the potentials of the transfer signal φh1 and the transfer signal φh2 are at “L (−3.3 V)” overlap. Accordingly, the ON states of the transfer thyristors Th1 to Th4 are shifted in order.

In FIG. 10, the transfer thyristor Th1 is in the ON state during the period from the time a1 to the time f2, the transfer thyristor Th2 is in the ON state during the period from the time f1 to the time k2, the transfer thyristor Th3 is in the ON state during the period from the time k1 to the time p2, and the transfer thyristor Th4 is in the ON state during the period from the time p1 to the time u1. The times k1 and k2 are between the time k and the time l, and the time k1 is earlier than the time k2. Furthermore, the times p1 and p2 are between the time p and the time q, and the time p1 is earlier than the time p2.

The same applies to the v-direction transfer part 103. The transfer signals φv1 and φv2 are set to be signals that exhibit “H (0 V)” and “L (−3.3 V)” such that periods during which the potentials of the transfer signal φv1 and the transfer signal φv2 are at “L (−3.3 V)” overlap. Accordingly, the ON states of the transfer thyristors Tv1 to Tv4 are shifted in order.

Regarding the setting period P(1), the transfer thyristor Tv1 is in the ON state during the period from the time a2 to the time b3, the transfer thyristor Tv2 is in the ON state during the period from the time b2 to the time c3, the transfer thyristor Tv3 is in the ON state during the period from the time c2 to the time d2, and the transfer thyristor Tv4 is in the ON state during the period from the time d1 to the time e2.

The setting periods P(2) to P(4) are similar to the setting period P(1).

At the times b, c, d, and e, by causing the potential of the setting signal φs to be shifted from “H (0 V)” to “L′ (−3 V)”, laser diodes LD that are connected to transfer thyristors Th in the ON state and transfer thyristors Tv in the ON state are turned ON. In contrast, at the times b, c, d, and e, by causing the setting signal φs to be maintained at “H (0 V)”, laser diodes LD that are connected to transfer thyristors Th in the ON state and transfer thyristors Tv in the ON state are maintained OFF.

That is, by allowing transfer thyristors Th and transfer thyristors Tv to be in the ON state, laser diodes LD to be set to ON or OFF are selected.

The case where the laser diodes LD are arranged in a 4 by 4 array has been described above. To increase the number of laser diodes LD in the h direction, the setting periods P(3) and P(4) may be repeated in FIG. 10. In contrast, to increase the number of laser diodes LD in the v direction, signals for the period from the time b to the time d may be inserted repeatedly from the time d in the setting period P(1) in FIG. 10. The same applies to the other setting periods P(2) to P(4).

The numbers of laser diodes LD in the light-emitting element part 101 are not necessarily the same between rows and between columns. That is, the number of laser diodes LD connected to setting thyristors S may not be the same. The number of laser diodes LD connected to a setting thyristor S may be one. The timing chart illustrated in FIG. 10 may be adjusted according to the number of laser diodes LD.

Furthermore, instead of providing the ON maintenance period Pc after the setting periods P(1) to P(4) for setting laser diodes LD to ON or OFF, the setting periods P(1) to P(4) for setting the laser diodes LD to ON or OFF may be repeated a plurality of times, so that gradation lighting may be performed. That is, for example, to implement 256 gradation levels, the setting periods P(1) to P(4) may be set to be repeated 255 times such that the individual laser diodes LD are turned ON at timings corresponding to desired gradation levels.

Furthermore, the signals (the transfer signals φh1, φh2, φv0, and φv2, the setting signal φs, and the ON signal Von) and the potentials (the h-direction power supply potential Vgk1, the v-direction power supply potential Vgk2, and the reference potential Vsub) described above are merely examples. Any values may be used as long as the light-emitting unit 100 may be caused to operate as described above.

In place of the coupling diodes Dh and Dv and the connection diodes Da and Db, resistors or the like may be used as long as variations in potential may be transmitted.

It is desirable that the row of the laser diodes LD that are turned ON first, such as the laser diodes LD11, LD21, LD31, and LD41, be arranged downstream on the v-gate signal lines 65 to 68 relative to the row of the laser diodes LD that are turned ON later, such as the laser diodes LD12, LD22, LD32, and LD42. With this arrangement, a situation in which the laser diodes LD and the driving thyristors U and B that are in the ON state are affected by operations of the laser diodes LD and the driving thyristors U and B that are to be turned ON later may be suppressed.

Furthermore, by adding a resistor or a diode in an appropriate position in a circuit or replacing a resistor with a diode, in accordance with a semiconductor material and driving voltage, a stable operation may be achieved. For example, the connection resistor Rc may be a connection diode.

As illustrated in FIG. 2, on the substrate 80 of the light-emitting unit 100, a φh1 terminal, a φh2 terminal, and a Vgk1 terminal may be provided in a direction that is substantially orthogonal to the arrangement of the transfer thyristors Th, and a φv1 terminal, a φv2 terminal, a Vgk2 terminal, and a φs terminal may be arranged in a direction that is substantially orthogonal to the arrangement of the transfer thyristors Tv. With this arrangement, depending on the arrangement of the plurality of laser diodes LD, current or/and voltage may be supplied uniformly.

Furthermore, by providing a thick-film insulating film made of benzocyclobutene (BCB) or the like on the h-direction transfer part 102 and the v-direction transfer part 103 (see FIG. 1) and providing a plurality of terminals (the φh1 terminal, the φh2 terminal, the Vgk1 terminal, the φv1 terminal, the φv2 terminal, the φs terminal, and the Von terminal) on the thick-film insulating film, reductions in the size and cost may be achieved. Furthermore, light from the transfer thyristors Th and the setting thyristors S may be blocked.

Furthermore, in this exemplary embodiment, the number of transfer thyristors Th is equal to the number of pieces of “i”, and each of the number of transfer thyristors Tv and the number of setting thyristors S is equal to the number of pieces of “j”. However, to increase the speed of driving of the light-emitting unit 100, a plurality of setting thyristors S may be connected to a single transfer thyristor Tv or a plurality of setting signal lines 64 may be provided. Furthermore, a plurality of light-emitting units 100 may be arranged on a substrate or divided substrates and driven in a parallel manner. With this arrangement, high-speed driving may be achieved.

As a modification of the light-emitting unit 100, a resistor may be connected between each of the cathodes of the connection diodes Da and the power supply line 51 in the equivalent circuit of the light-emitting unit 100 illustrated in FIG. 1. In a similar manner, a resistor may be connected between each of the cathodes of the connection diodes Db (between the cathodes of the connection diodes Db and the connection resistors Rc) and the power supply line 61. With this arrangement, the potentials of the gates of the driving thyristors U and the gates of the driving thyristors B may be controlled mode reliably, and a more stable operation of the light-emitting unit 100 may thus be achieved.

Furthermore, by adding a resistor or a diode in an appropriate position in a circuit or replacing a resistor with a diode, in accordance with a semiconductor material and driving voltage, a stable operation may be achieved. For example, the connection resistor Rc may be a connection diode.

In the explanation provided above, a current constriction layer is provided at the p-anode layer 81. However, the current constriction layer may be provided at other layers. For example, the current constriction layer may be provided at the n-cathode layer 89, the p-anode layer 91, or the n-cathode layer 95.

Furthermore, although the laser diodes LD are provided on the substrate 80 in the explanation provided above, the driving thyristors U, the driving thyristors B, and the laser diodes LD may be laminated from the substrate 80 side.

Furthermore, the laser diodes LD may be provided between the driving thyristors U and the driving thyristors B. When a driving thyristor U and a driving thyristor B are directly connected, the driving thyristor U and the driving thyristor B easily operate.

In place of the laser diodes LD, light-emitting diodes LED may be provided.

In the case where the h-direction power supply potential Vgk1 and the v-direction power supply potential Vgk2 are set to the same potential “L (−3.3 V)” and may be used at the same potential, the h-direction power supply potential generation part 170 and the v-direction power supply potential generation part 180 may be integrated together.

Furthermore, although the transfer thyristors Th and Tv are connected by the coupling diodes Dh and Dv in the explanation provided above, the transfer thyristors Th and Tv may be connected by coupling transistors, in place of the coupling diodes.

### [Optical Measuring Instrument]

The light-emitting apparatus 10 described above may be used for optical measurement.

FIG. 16 is a diagram for explaining an optical measuring instrument 1 including the light-emitting apparatus 10.

The optical measuring instrument 1 includes the light-emitting apparatus 10 described above, a light-receiving unit 11 that receives light, and a processing unit 12 that processes data. A measurement target (target) 13 is placed facing the optical measuring instrument 1. In FIG. 16, for example, the measurement target 13 is a person. FIG. 16 is a diagram viewed from above.

The light-emitting apparatus 10 turns ON the laser diodes LD that are arranged two-dimensionally as described above, and emits light spread in a conical shape centered on the light-emitting apparatus 10, as indicated by solid lines.

The light-receiving unit 11 is a unit that receives light reflected by the measurement target 13. The light-receiving unit 11 receives light directed toward the light-receiving unit 11, as indicated by broken lines. The light-receiving unit 11 may be an imaging device that receives light two-dimensionally.

The processing unit 12 is configured as a computer including an input/output unit that inputs/outputs data. The processing unit 12 processes information regarding light to calculate the distance to the measurement target 13 and the three-dimensional shape of the measurement target 13.

The processing unit 12 of the optical measuring instrument 1 controls the light-emitting apparatus 10 and causes the light-emitting apparatus 10 to emit light for a short period. That is, the light-emitting apparatus 10 emits light in a pulse manner. Thus, the processing unit 12 calculates the optical length of light emitted from the light-emitting apparatus 10, reflected by the measurement target 13, and reaching the light-receiving unit 11, based on a time difference between the time at which the light-emitting apparatus 10 emits light and the time at which the light-receiving unit 11 receives reflected light from the measurement target 13. The positions of the light-emitting apparatus 10 and the light-receiving unit 11 and the distance between the light-emitting apparatus 10 and the light-receiving unit 11 are determined in advance. Therefore, the processing unit 12 calculates the distance to the measurement target 13, based on the distances from the light-emitting apparatus 10 and the light-receiving unit 11 or a reference point (hereinafter, represented by a reference point). The reference point represents a point provided at a predetermined position from the light-emitting apparatus 10 and the light-receiving unit 11.

This method is a measurement method based on the arrival time of light and is called a time of flight (TOF) method.

By performing this method for a plurality of points on the measurement target 13, the three-dimensional shape of the measurement target 13 is measured. As described above, light emitted from the light-emitting apparatus 10 spreads two-dimensionally and is applied to the measurement target 13. Reflected light from a part of the measurement target 13 with a short distance from the light-emitting apparatus 10 is first incident to the light-receiving unit 11. In the case where an imaging device that acquires the two-dimensional image mentioned above is used, bright spots are recorded in parts reflected light has reached in frame images. Based on the bright spots recorded in a series of frame images, the optical length is calculated. Then, the distances from the light-emitting apparatus 10 and the light-receiving unit 11 or the distance from the reference point is calculated. That is, the three-dimensional shape of the measurement target 13 is calculated.

Furthermore, the light-emitting apparatus 10 according to this exemplary embodiment may be used for, as another method, an optical measurement method using a structured light system. An instrument to be used for the structure light system is substantially the same as the optical measuring instrument 1 including the light-emitting apparatus 10 illustrated in FIG. 16. The instrument to be used for the structured light system is different from the optical measuring instrument 1 in that light applied to the measurement target 13 has a pattern of a myriad of light dots (random pattern) and the light-receiving unit 11 receives the light having such a pattern. Then, the processing unit 12 processes information regarding the light. In the process, the time difference described above is not obtained. Instead, the processing unit 12 calculates the amount of misregistration of the myriad of light dots to obtain the distance to the measurement target 13 and the three-dimensional shape of the measurement target 13. As a light source used for this known system, a randomly arranged two-dimensional VCSEL array or the like is used. An irradiation random pattern includes, for example, predetermined one to four patterns (a structured light Fix system). In contrast, the light-emitting apparatus 10 according to this exemplary embodiment is able to set desired light dots to apply, according to an external signal, in this case, a setting signal φs. Therefore, light may be applied with more random patterns (a structured light programmable system).

As described above, the optical measuring instrument 1 may be applicable to calculation of a distance to an object. The optical measuring instrument 1 may also be applicable to calculation of the shape of an object to identify the object. The optical measuring instrument 1 may also be applicable to calculation of the shape of the face of a person for identification (face authentication). Furthermore, the optical measuring instrument 1 may be mounted on a vehicle to be applicable to detection of an obstacle at the front, rear, or sides of the vehicle. As described above, the optical measuring instrument 1 may be widely used for calculation of the distance, shape, and the like.

### [Image Forming Apparatus]

The light-emitting apparatus 10 described above may be used for image formation for forming images.

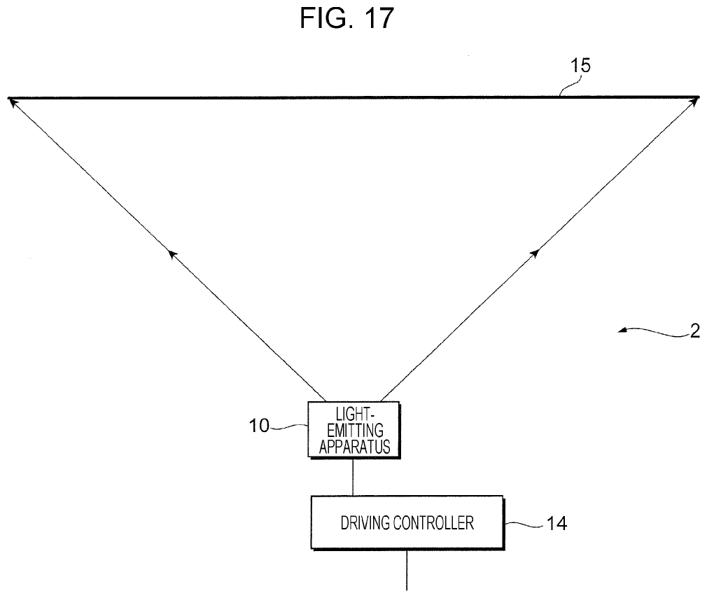

FIG. 17 is a diagram for explaining an image forming apparatus 2 including the light-emitting apparatus 10.

The image forming apparatus 2 includes the light-emitting apparatus 10 described above, a driving controller 14, and a screen 15 for receiving light.

An operation of the image forming apparatus 2 will be explained below.

As described above, the light-emitting apparatus 10 sets the laser diodes LD that are arranged two-dimensionally to ON or OFF. During the ON maintenance period Pc, the light-emitting apparatus 10 causes the laser diodes LD to be turned ON in a parallel manner. That is, a two-dimensional static image (two-dimensional image) may be obtained. Therefore, the driving controller 14, which receives input of image signals and drives the light-emitting apparatus 10 in accordance with the image signals such that two-dimensional images are formed, sequentially rewrites the ON maintenance period Pc as a frame, and moving images of two-dimensional images may thus be obtained. Such two-dimensional static images and moving images are projected to the screen 15.

In the explanation provided above, the laser diodes LD are turned ON or OFF. However, all the laser diodes LD may be set to a light emission state in advance and may be controlled to increase the light emission intensity. Furthermore, light-emitting diodes LED may be used in place of laser diodes LD.

The foregoing description of the exemplary embodiments of the present disclosure has been provided for the purposes of illustration and description. It is not intended to be exhaustive or to limit the disclosure to the precise forms disclosed. Obviously, many modifications and variations will be apparent to practitioners skilled in the art. The embodiments were chosen and described in order to best explain the principles of the disclosure and its practical applications, thereby enabling others skilled in the art to understand the disclosure for various embodiments and with the various modifications as are suited to the particular use contemplated. It is intended that the scope of the disclosure be defined by the following claims and their equivalents.

What is claimed is:

1. A light-emitting apparatus comprising:
a plurality of first transfer elements that enter an ON state in order;
a plurality of second transfer elements that enter the ON state in order;
a plurality of first driving elements that are connected to the plurality of first transfer elements and are shifted to a state in which the plurality of first driving elements are able to be shifted to the ON state, when the first transfer elements enter the ON state;
a plurality of setting elements that are connected to the plurality of second transfer elements and are shifted to a state in which the plurality of setting elements are able to be shifted to the ON state, when the second transfer elements enter the ON state;
a plurality of second driving elements that are connected to the plurality of setting elements and are shifted to a state in which the plurality of second driving elements are able to be shifted to the ON state, when the setting elements enter the ON state; and
a plurality of light-emitting elements that are connected to the plurality of first driving elements and the plurality of second driving elements and emit light or increase light emission intensity when the first driving elements and the second driving elements enter the ON state,
wherein a plurality of sets each including one of the first driving elements, one of the second driving elements, and one of the light-emitting elements are connected to at least one of the plurality of setting elements, and the plurality of light-emitting elements are arranged two-dimensionally.

2. The light-emitting apparatus according to claim 1, wherein a plurality of sets each including one of the first driving elements, one of the second driving elements, and one of the light-emitting elements are connected to each of the plurality of setting elements.

3. The light-emitting apparatus according to claim 1, wherein the first driving element, the second driving element, and the light-emitting element in each of the sets are connected in series and arranged such that current for causing the light-emitting element to emit light or increase the light emission intensity flows via the first driving element and the second driving element that have been shifted from an OFF state to the ON state.

4. The light-emitting apparatus according to claim 3, further comprising:
an ON electrode that is arranged to be shared among the sets each including the first driving element, the second driving element, and the light-emitting element that are connected in series,
wherein the current for causing the light-emitting element to emit light or increase the light emission intensity is supplied from the ON electrode.

5. The light-emitting apparatus according to claim 3, wherein the first driving element, the second driving element, and the light-emitting element are laminated and connected in series.

6. The light-emitting apparatus according to claim 5, further comprising:
a reference electrode that supplies reference potential; and
an ON electrode that supplies current for causing the light-emitting element to emit light or increase the light emission intensity,
wherein the first driving element, the second driving element, and the light-emitting element are laminated in an order of the first driving element, the second driving element, and the light-emitting element, the reference electrode is connected on a side of the light-emitting element, and the ON electrode is connected on a side of the first driving element.

7. The light-emitting apparatus according to claim 1, further comprising a controller that performs control such that the plurality of light-emitting elements that are arranged two-dimensionally maintain the ON state in a parallel manner.

8. The light-emitting apparatus according to claim 7, wherein the controller performs control such that ON-target light-emitting elements, out of the plurality of light-emitting elements that are arranged two-dimensionally, are turned on sequentially and such that after sequential tuning on is completed, the plurality of light-emitting elements that have been sequentially turned on maintain the ON state in the parallel manner.

9. The light-emitting apparatus according to claim 7,
wherein the controller performs control such that during a first period, ON-target light-emitting elements, out of a plurality of light-emitting elements that are connected to first transfer elements in the ON state, out of the plurality of first transfer elements, are turned on sequentially by the plurality of second transfer elements,
wherein the controller performs control such that during a second period subsequent to the first period, ON-target light-emitting elements, out of a plurality of light-emitting elements that are connected to first transfer elements that are turned on next, out of the plurality of first transfer elements, are turned on sequentially by the plurality of second transfer elements, and
wherein the controller performs control such that during a third period subsequent to the second period, the plurality of light-emitting elements that are turned on during the first period and the second period maintain the ON state in the parallel manner.

10. The light-emitting apparatus according to claim 9, wherein the controller performs control such that the third period is longer than the first period.

11. The light-emitting apparatus according to claim 1,
wherein the plurality of driving elements are thyristors each including a first gate terminal,
wherein the plurality of second driving elements are thyristors each including a second gate terminal,
wherein the plurality of first driving elements are connected to the plurality of first transfer elements via the first gate terminals, and
wherein the plurality of second driving elements are connected to the plurality of setting elements via the second gate terminals.

12. An optical measuring instrument comprising:
the light-emitting apparatus according to claim 1;
a light-receiving unit that receives reflected light from a target irradiated with light by the light-emitting apparatus; and
a processing unit that processes information regarding the light received by the light-receiving unit and measures a distance from the light-emitting apparatus to the target or a shape of the target.

13. An image forming apparatus comprising:
the light-emitting apparatus according to claim 1; and
a driving controller that receives input of an image signal and drives the light-emitting apparatus in accordance with the image signal such that a two-dimensional image is formed by light emitted from the light-emitting apparatus.

14. A light-emitting device comprising:
a first thyristor that includes a first gate;
a second thyristor that includes a second gate; and
a light-emitting element,
wherein the first thyristor, the second thyristor, and the light-emitting element are laminated and connected in series.

15. The light-emitting device according to claim 14, wherein when a predetermined voltage is applied to a multilayer body including the first thyristor, the second thyristor, and the light-emitting element that are laminated, and the first thyristor and the second thyristor are shifted from the OFF state to the ON state in accordance with a control signal input to each of the first gate of the first thyristor and the second gate of the second thyristor, the light-emitting element emits light or increases the light emission intensity.

16. The light-emitting device according to claim 15, wherein the first thyristor and the second thyristor are laminated so as to be connected in the multilayer body.
